(19) United States
(12) Patent Application Publication
(10) Pub. No.: US 2023/0344381 A1
(43) Pub. Date: Oct. 26, 2023

(54) Rubber Molded Articles that Integrally Incorporate a Photovoltaic Device, and Method and System for Producing Such Articles

(71) Applicant: SOLARPAINT LTD., YOKNEAM ILLIT (IL)

(72) Inventors: Eran Maimon, Kibbutz Nahsholim (IL); Ramon Joseph Albalak, Haifa (IL)

(21) Appl. No.: 18/217,620

(22) Filed: Jul. 3, 2023

Related U.S. Application Data
(63) Continuation-in-part of application No. 18/136,359, filed on Apr. 19, 2023.
(63) Continuation-in-part of application No. 18/129,865, filed on Apr. 2, 2023.
Application No. PCT/IL2022/050030 is a continuation-in-part of application No. 17/802,335, filed on Aug. 25, 2022.
(63) Continuation-in-part of application No. 17/802,335, filed on Aug. 25, 2022.
(63) Continuation of application No. PCT/IL2022/050030, filed on Jan. 10, 2022.
Application No. PCT/IL2022/050030 is a continuation-in-part of application No. PCT/IL2021/051269, filed on Oct. 27, 2021.
Application No. 18/136,359 is a continuation of application No. PCT/IL2021/051269, filed on Oct. 27, 2021.
Application No. PCT/IL2022/050030 is a continuation-in-part of application No. PCT/IL2021/051202, filed on Oct. 7, 2021.
Application No. 18/129,865 is a continuation of application No. PCT/IL2021/051202, filed on Oct. 7, 2021.
Application No. PCT/IL2022/050030 is a continuation-in-part of application No. 17/353,867, filed on Jun. 22, 2021.
(63) Continuation-in-part of application No. 17/353,867, filed on Jun. 22, 2021.
Application No. PCT/IL2021/051202 is a continuation-in-part of application No. 17/353,867, filed on Jun. 22, 2021.
Application No. PCT/IL2021/051269 is a continuation-in-part of application No. 17/353,867, filed on Jun. 22, 2021.
Application No. 17/353,867 is a continuation-in-part of application No. PCT/IL2019/051416, filed on Dec. 26, 2019.
Application No. 17/353,867 is a continuation-in-part of application No. 16/362,665, filed on Mar. 24, 2019, now Pat. No. 11,081,606.
Application No. PCT/IL2019/051416 is a continuation-in-part of application No. 16/362,665, filed on Mar. 24, 2019, now Pat. No. 11,081,606.
(60) Provisional application No. 63/135,898, filed on Jan. 11, 2021.
(60) Provisional application No. 63/106,666, filed on Oct. 28, 2020.
(60) Provisional application No. 63/088,535, filed on Oct. 7, 2020.
(60) Provisional application No. 62/982,536, filed on Feb. 27, 2020.
(60) Provisional application No. 62/982,536, filed on Feb. 27, 2020.
(60) Provisional application No. 62/785,282, filed on Dec. 27, 2018.
(60) Provisional application No. 62/785,282, filed on Dec. 27, 2018.

(51) Int. Cl. H02S 30/20; H02S 20/25; B29C 45/00; H02S 20/21; H02S 20/10; B29C 45/14

(52) U.S. Cl. CPC H02S 30/20; B29C 45/0001; B29C 45/14778; H02S 20/10; H02S 20/21; H02S 20/25; B63B 2035/4453

(57) ABSTRACT

Rubber molded articles that integrally incorporate an operable photovoltaic device, and method and system for producing such articles. An apparatus includes a rubber body, formed of one or more solidified, compacted, previously-heated rubber materials, selected from the group consisting of: virgin unused rubber material, recycled rubber, scrap rubber, rubber pellets, rubber granules, rubber lumps, rubber strips. The apparatus also includes an operable photovoltaic device, that is configured to generate electricity from light via the photovoltaic effect; and which is optionally flexible and rollable. The operable photovoltaic device is integrally held on top of the rubber body, via a molded connection and holding mechanism which molds together the rubber body and the operable photovoltaic device.

### CROSS REFERENCE TO RELATED APPLICATIONS

This patent application is a Continuation of PCT international application number PCT/IL2022/050030, having an international filing date of Jan. 10, 2022, which is hereby incorporated by reference in its entirety.

The above-mentioned PCT/IL2022/050030 claims priority and benefit from US 63/135,898, filed on Jan. 11, 2021, which is hereby incorporated by reference in its entirety.

This above-mentioned PCT/IL2022/050030 also claims priority and benefit from US 17/353,867, filed on Jun. 22, 2021, which is hereby incorporated by reference in its entirety.

The above-mentioned PCT/IL2022/050030 also claims priority and benefit from PCT international application number PCT/IL2021/051269, having an international filing date of Oct. 27, 2021, which is hereby incorporated by reference in its entirety.

The above-mentioned PCT/IL2022/050030 also claims priority and benefit from international application number PCT/IL2021/051202, having an international filing date of Oct. 7, 2021, which is hereby incorporated by reference in its entirety.

This patent application is also a Continuation-in-Part (CIP) of US 17/353,867, filed on Jun. 22, 2021, which is hereby incorporated by reference in its entirety.

The above-mentioned US 17/353,867 is a Continuation-in-Part (CIP) of US 16/362,665, filed on Mar. 24, 2019, now Pat. No. US 11,081,606 (issued on Aug. 3, 2021), which is hereby incorporated by reference in its entirety; which claims priority and benefit from US 62/785,282, filed on Dec. 27, 2018, which is hereby incorporated by reference in its entirety.

The above-mentioned US 17/353,867 is also a Continuation-in-Part (CIP) of PCT international application number PCT/IL2019/051416, having an international filing date of Dec. 26, 2019, which is hereby incorporated by reference in its entirety.

The above-mentioned PCT/IL2019/051416 claims priority and benefit (I) from US 16/362,665, filed on Mar. 24, 2019, now Pat. No. US 11,081,606 (issued on Aug. 3, 2021), which is hereby incorporated by reference in its entirety, and (II) from US 62/785,282, filed on Dec. 27, 2018, which is hereby incorporated by reference in its entirety.

The above-mentioned PCT/IL2022/050030 is also a Continuation-in-Part (CIP) of US 17/802,335, filed on Aug. 25, 2022, which is hereby incorporated by reference in its entirety; which is a National Stage of PCT international application number PCT/IL2021/050217, having an international filing date of Feb. 25, 2021, which is hereby incorporated by reference in its entirety; which claims priority and benefit from US 62/982,536, filed on Feb. 27, 2020, which is hereby incorporated by reference in its entirety.

This patent application is also a Continuation-in-Part (CIP) of US 18/129,865, filed on Apr. 2, 2023, which is hereby incorporated by reference in its entirety. The above-mentioned US 18/129,865 is a Continuation of PCT international patent application number PCT/IL2021/051202, having an international filing date of Oct. 7, 2021, which is hereby incorporated by reference in its entirety. The above-mentioned PCT/IL2021/051202 claims priority and benefit from (i) US 63/088,535, filed on Oct. 7, 2020, which is hereby incorporated by reference in its entirety; and from (ii) US 17/353,867, filed on Jun. 22, 2021, which is hereby incorporated by reference in its entirety.

This patent application is also a Continuation-in-Part (CIP) of US 18/136,359, filed on Apr. 19, 2023, which is hereby incorporated by reference in its entirety. The above-mentioned US 18/136,359 is a Continuation of PCT international application number PCT/IL2021/051269, having an international filing date of Oct. 27, 2021, which is hereby incorporated by reference in its entirety. The above-mentioned PCT/IL2021/051269 claims priority and benefit: (i) from US 63/106,666, filed on Oct. 28, 2020, which is hereby incorporated by reference in its entirety; and also, (ii) from US 17/353,867, filed on Jun. 22, 2021, which is hereby incorporated by reference in its entirety.

This patent application is also a Continuation-in-Part (CIP) of US 17/802,335, filed on Aug. 25, 2022, which is hereby incorporated by reference in its entirety; which is a National Stage of PCT international application number PCT/IL2021/050217, having an international filing date of Feb. 25, 2021, which is hereby incorporated by reference in its entirety; which claims priority and benefit from US 62/982,536, filed on Feb. 27, 2020, which is hereby incorporated by reference in its entirety.

### FIELD

Some embodiments relate to the field of solar panels and photovoltaic (PV) devices.

### BACKGROUND

The photovoltaic (PV) effect is the creation of voltage and electric current in a material upon exposure to light. It is a physical and chemical phenomenon.

The PV effect has been used in order to generate electricity from sunlight. For example, PV solar panels absorb sunlight or light energy or photons, and generate current electricity through the PV effect.

### SUMMARY

Some embodiments provide rubber-based articles (e.g., rubber-molded articles, molded rubber articles, articles formed by rubber injection molding, articles formed by rubber compression molding, articles formed by rubber transfer molding or rubber transfer-compression molding). The molded rubber articles or the rubber-based articles, integrally incorporate an operable photovoltaic device.

For example, an apparatus includes a rubber body, formed of one or more solidified, compacted, previously-heated rubber materials, selected from the group consisting of: virgin unused rubber material, recycled rubber, scrap rubber, rubber pellets, rubber granules, rubber lumps, rubber strips. The apparatus also includes an operable photovoltaic device, that is configured to generate electricity from light via the photovoltaic effect; and which is optionally flexible and rollable. The operable photovoltaic device is integrally held on top of the rubber body, via a molded connection and holding mechanism which molds together the rubber body and the operable photovoltaic device.

Some embodiments provide rubber injection molded articles, that integrally incorporate therein or thereon an integrated photovoltaic (PV) device or solar panel; as well as methods and systems for producing such articles.

Some embodiments provide rubber compression molded articles, that integrally incorporate therein or thereon an integrated photovoltaic (PV) device or solar panel; as well as methods and systems for producing such articles.

Some embodiments provide rubber transfer molded articles (or rubber transfer-compression molded articles), that integrally incorporate therein or thereon an integrated photovoltaic (PV) device or solar panel; as well as methods and systems for producing such articles.

Some embodiments provide other and/or additional benefits and/or advantages.

### BRIEF DESCRIPTION OF THE DRAWINGS

FIG. 1 is a flow-chart of a method of producing via injection rubber molding a rubber-based or elastomeric article having one or more integrated PV device(s), in accordance with some embodiments.

FIG. 2 is a flow-chart of a method of producing via compression rubber molding a rubber-based or elastomeric article having integrated PV device(s), in accordance with some embodiments.

FIG. 3 is a flow-chart of a method of producing, via rubber transfer molding (or, via rubber transfer-compression molding), a rubber-based or elastomeric article having integrated PV device(s), in accordance with some embodiments.

FIGS. 4A to 4G are schematic illustrations demonstrating components and operational steps of a rubber molding system, in accordance with some demonstrative embodiments.

FIGS. 5A to 5C are illustrations of several prior art hybrid non-monolithic products.

FIGS. 6A to 6F are schematic side-view illustrations of several monolithic molded articles, in accordance with some embodiments.

FIGS. 7A to 7D demonstrate four steps in a production process of a rubber-based article having a PV device that is integrally integrated with (or incorporated in) a rubber-based body, in accordance with some embodiments.

FIG. 7E is a schematic illustration of an integrated molded article, in accordance with some demonstrative embodiments.

FIG. 7F is a schematic illustration of another integrated molded article, in accordance with some demonstrative embodiments.

FIG. 8A is a schematic illustration of a top-side view of a set of pavement tiles, in accordance with some demonstrative embodiments.

FIG. 8B is a schematic illustration of a side-side view of that set of pavement tiles, in accordance with some demonstrative embodiments.

FIG. 9A is a schematic illustration of a top-side view of another set of pavement tiles, in accordance with some demonstrative embodiments.

FIG. 9B is a schematic illustration of a side-side view of that other set of pavement tiles, in accordance with some demonstrative embodiments.

### DETAILED DESCRIPTION OF SOME DEMONSTRATIVE EMBODIMENTS

Some embodiments provide a photovoltaic (PV) device or an article or an apparatus, that integrally includes one or more regions formed of rubber, and particularly formed of recycled rubber or recycled rubber granules or recycled rubber pellets; as well as methods and systems for producing such PV device or apparatus.

A solar cell, or photovoltaic (PV) cell, is a device that converts the energy of light or sunlight or photons directly into electricity by the photovoltaic effect, a physical and chemical phenomenon. Commonly used solar cells are configured as a large-area p-n junction made from silicon. Other solar cell types are, for example, thin film like CdTe or CIGS, organic solar cells, dye sensitized solar cells, perovskite solar cells, quantum dot solar cells etc.

Some solar cells operate according to the following: (1) Photons in sunlight hit the solar panel and are absorbed by semiconducting materials, such as silicon; (2) Electrons are excited by the photons from their current molecular/atomic orbital in the semiconducting material; (3) Once excited an electron can either dissipate the energy as heat and return to its orbital or travel through the cell until it reaches an electrode; (4) Current flows through the material to cancel the potential and this electricity is captured. The chemical bonds of the solar cell material are important for this process to work, and usually silicon is used in two regions, one region being doped with boron, the other phosphorus. These regions have different chemical electric charges and subsequently both drive and direct the current of electrons towards a relevant electrode.

An array of solar cells converts solar energy into a usable amount of direct current (DC) electricity. Individual solar cell devices can be combined to form modules, otherwise known as solar panels. In some cases, an inverter can convert DC current / power from a panel into alternating current (AC).

The Applicants have realized that conventional articles that include a solar cell, are typically manufactured in a multiple-step method. First, the article itself is produced or manufactured, such as from plastic. Second, the solar cell or solar panel is produced, separately and by itself; often in an entirely different location or facility; and is transported to the location or facility where the article is produced. Third, the solar cell or solar panel is connected or glued or attached to the article; for example, using glue, or using screws, or using other mechanical connection mechanism, often via manual labor, and sometimes in an automated or semi-automated connection process.

The Applicants have realized that conventional articles having PV energy generation capabilities are conventionally produced by manufacturing a finished or almost-finished or nearly-finished or essentially-finished article, and then by attached to it a solar cell or a solar panel in a subsequent manufacturing process and via a mechanical connection process.

The Applicants have realized that such conventional production methods and production system, as well as the article that results from them, may have one or more disadvantages. For example, realized the Applicants, the step of mechanical connection of the solar panel to the almost-finished article, may be labor intensive and/or time consuming and/or error prone. Additionally or alternatively, realized the Applicants, it may require delicate and/or precise manual labor, sometimes requiring manual gluing or manual utilization of screws and screwdrivers; and sometimes causing inadvertent breaking or cracking or damage to the solar cell and/or to the article itself due to such step of mechanical connection. Additionally or alternatively, realized the Applicants, the mechanical connection may be non-resilient to shocks or forces that are subsequently applied to the article (e.g., when the article is transported, installed, and/or utilized); for example, a screw-based connector may fail or may become loose or open; a glue-based connection may fall apart or may weaken due to environmental heat; or the like. Additionally or alternatively, realized the Applicants, the mechanical connection sometimes causes the final article to have visible and/or structural gaps or air-gaps that may be undesired; for example, the solar cell or solar panel is sometimes attached to the article via screws, in a manner that is not entirely tight and/or secure and/or hermetic, which allows water or liquids to flow through thin gaps that may remain between the solar cell and an adjacent region of the article; and possibly allowing such water or liquid to damage interior component(s) of the finished article.

The applicants have also realized that conventional production methods of various products that are formed of rubber or that include rubber, do not allow for efficient manufacturing of such an article having incorporated therein or having embedded therein a PV device or a solar cell, at all or at least at a curved region of the article or at a non-planar or non-flat region of the article.

The Applicants have realized that there is a need to embed, connected, integrate and/or incorporate a solar cell or a solar panel or other PV device or PV-based electricity generating unit, into an article of manufacture that is formed of rubber or recycled rubber, in a manner that is more efficient, more secure, less prone to attachment errors or attachment problems, less labor consuming, and more or fully automated manner; as well as a need for producing a finished article that is formed of rubber or recycled rubber, and having such solar cell integrated therein or thereon, which is more resilient to mechanical shocks and forces, and/or is more leak-proof or water-proof or liquid-proof, and/or has a secure and tight and integral connection to a surrounding or adjacent or neighboring region or part of the article itself.

Some embodiments provide methods and systems for producing an article, and particularly an article formed exclusive of rubber or recycled rubber or formed dominantly from rubber or recycled rubber, by performing one or more rubber molding process(es) such that the solar cell or solar panel or other PV device is inserted or added or placed as an “insert” item, before or during such rubber molding process, and becomes integrally integrated or embedded or incorporated in the article during the molding process; without a subsequent need to perform a gluing step or a screwing of screws step or other mechanical connection step; and such that the molding itself, upon cooling down of the article, causes the solar panel or PV device to be integrally embedded and/or connected and/or attached and/or held in place within or on the finished article.

The term “Natural Rubber” as used herein may include, for example: rubber formed of latex or polymers or elastomers that are obtained or extracted from a rubber tree and/or a rubber plant and/or a rubber vine; for example, India rubber, caucho, caoutchouc, rubber consisting mainly of polymers of the organic compound isoprene, rubber made from plant-based latex or latex milk, rubber made from tree-based latex or latex-milk, rubber made from vine-based latex or latex-milk, rubber made from latex obtained from the Amazonion rubber tree or Hevea brasiliensis, or from the Pará rubber tree or from the sharinga tree or from seringueira; rubber obtained from Amazonian rubber tree (Hevea brasiliensis); rubber obtained from Congo rubber plants or trees (e.g., Landolphia owariensis, Landolphia kirkii, Landolphia heudelotis); rubber made of latex from dandelion milk or dandelion plants; non-vulcanized rubber; non-crosslinked rubber; or the like.

The terms “Synthetic Rubber” as used herein may include any rubber formed of synthetic elastomers or synthetic polymers; for example, rubber made of polymers synthesized from petroleum byproducts or crude oil; Styrene-Butadiene Rubber (SBR), for example, derived from the copolymerization of styrene and 1,3-butadiene; polyisoprene, prepared by polymerization of synthetic isoprene; chloroprene, prepared by polymerization of 2-chlorobutadiene; nitrile rubber, made from cyanobutadiene or 2-propenenitrile and butadiene; Acrylic Rubber (ACM); Butadiene Rubber (BR); styrene-butadiene block copolymers (SBC); transparent or partially-transparent SBC; or translucent or partially-translucent SBC; styrene-isoprene block copolymers (SIS); Poly(styrene-butadiene-styrene) (SBC); Poly(styrene-isoprene-styrene) (SIS); Poly(styrene-ethylene/butylene-styrene) (SEBS); post-vulcanization rubber or elastomers; vulcanized rubber or elastomers; crosslinked rubber or elastomers; non-vulcanized rubber or elastomers; rubber that undergoes or underwent vulcanization (e.g., via curing and/or cross-linking with Sulfur); Neoprene or poly-chloroprene, or rubber produced by polymerization of chloroprene; Butyl Rubber (IIR); Chlorosulfonated Polyethylene (CSM) or Hypalon rubber; Ethylene Propylene Diene Monomer (EPDM) rubber; Fluoroelastomers (FKM) / Viton rubber; Isoprene Rubber (IR); Nitrile Rubber (NBR); Perfluoro-elastomer (FFKM) rubber; Poly-Chloroprene (CR) / Neoprene rubber; Poly-sulfide Rubber (PSR); and/or other types of synthetic rubber and/or laboratory-made rubber and/or non-natural rubber.

The term “Recycled Rubber” as used herein may include for example: granules or pellets or particles or mulch or strips of an already-produced article and/or a previously-used article that is formed of natural rubber and/or synthetic rubber; for example, granules or pellets or strips or particles or mulch that are obtained by cutting or dicing or chopping or grinding or crushing or smashing or mincing a rubber article; ground or crushed or minced or chopped or smashed or diced or cut granules or pellets or strips or particles from an already-produced and/or pre-used rubber products (e.g., rubber tires; rubber shoes; rubber soles; rubber footwear; rubber cookware; rubber bands; rubber gloves; or the like); granules or pellets or particles or mulch that were reclaimed from scrap rubber; granules or pellets or strips or particles or mulch that were obtained by shredding of scrap rubber or previously-used rubber products or previously-manufactured rubber products by powerful interlocking knives or blades that perform chopping operations; granules or pellets or strips or particles or mulch that were obtained from cryogenic freezing of rubber products or scrap rubber to a sub-zero temperature that causes the rubber to become brittle such that a powerful hammer or similar machine can smash or crush the frozen rubber into small pieces; or the like.

Some embodiments include methods and systems for producing a variety of electricity producing articles, that are capable of generating electricity from sunlight or light using the PV effect, and that contain (or are formed dominantly or partially of) rubber, recycled rubber, natural rubber, synthetic rubber, a mixture of natural and synthetic rubber, pellets or granules or mulch or strips of natural rubber or of recycled natural rubber, pellets or granules or strips or mulch of synthetic rubber or of recycled synthetic rubber, a mixture of pellets or granules or mulch or strips of natural rubber and/or synthetic rubber and/or recycled natural rubber and/or recycled synthetic rubber.

In some embodiments, the manufactured article may have one or more curved or non-planar or non-flat contours or edges or regions or borders or surfaces, which may include a PV device having resilience to varying stress patterns and/or mechanical forces and/or mechanical shocks that may be exerted upon the article and/or that the article may be exposed to. Accordingly, a flexible and/or rollable and/or foldable solar cell or solar panel or PV device may be used, due to their flexibility and/or elasticity and/or resilience properties; to endure and/or to absorb and/or to dissipate the stresses or forces or shocks that may be encountered during the fabrication process or during the manufacturing process and also during the subsequent utilization of the article. Such flexible and/or rollable and/or foldable solar cell or solar panel or PV device may be adapted to be integrated at, or in, or on, or as part of, such curved or non-plat or non-planar region or surface of the article, and may absorb stresses or forces or shocks without harming or damaging their performance and/or their structure; and while preventing or avoiding the PV device or the solar panel from breaking or shattering or cracking or becoming non-operational. In some embodiments, the article may be formed via a molding or compression molding process, and/or via a compacting process, and/or via a process that involves high temperatures or intense heating and/or melting processes; and thus such resilient solar panel or PV device may be integrally used in the manufacturing process of the article, as it can endure such processes.

In some embodiments, the manufacturing process includes the attachment or placement or positioning of one or more PV devices onto (or on, or at) one or more surfaces of a mold; and pouring rubber and/or recycled rubber (e.g., as granules or pellets of mulch or aggregates) and one or more binders or binding agents (e.g., polyurethane-based binders) over and/or around and/or near these elements; and subsequently, applying pressure and heat for a pre-determined time-period, thereby causing the rubber and the placed PV device(s) to form an integral or integrated or monolithic part of the same finished article.

The PV device(s) and/or their electricity-generating components may be electrically connected to each other, in parallel and/or in series, thereby building up or aggregating or accumulating electric current and/or electric voltage. The arrangement of PV device(s) or electricity-generating components may terminate or end in, or may be connected to, one or more sets of terminals or electrodes, enabling to connect the PV device(s) to an external load or energy storing device, to an external or nearby battery or power cell or rechargeable battery or rechargeable power cell, to an electronic device or an electric device that immediately consumes or utilizes the generated electricity, to an electricity-storing device, or the like.

In some embodiments, such electronic devices or components, and/or electricity-storing devices or components, as well as suitable electric connectors, may be integrally embedded inside the rubber or rubber-based body or region or portion of the finished article. In some embodiments, an outer or external part of region, that is located between the PV device(s) and the mold, may be encapsulated by a transparent or translucent or semi-transparent or semi-translucent or partially-transparent or partially-translucent material or layer. Such outer or external part or region may optionally be formed of one or more layers, optionally including a moisture barrier, a liquid absorbing barrier or agent, a liquid blocking barrier or agent or layer, a moisture blocking layer or agent, a mechanical shock absorbing layer or material, a layer having electrical insulation properties, a net or mesh for mechanical fortification of the article’s surface in one or more particular directions, a thermal protection layer, a mechanical forces absorption layer, and/or other suitable layers or barriers or protection layers or encapsulation layers.

Optionally, the rubber molded article may be structured in accordance with a particular pre-defined structure or shape or three-dimensional structure, which may operate as micro-lenses and/or as light focusing elements, and/or which may enhances or improve or increase light absorption onto one or more active regions of the PV device and/or which may tunnel or channel or direct incoming light towards a particular region and/or away from a particular region. Optionally, such layers may include one or more elements or components that convert parts of the incident radiation spectrum to wavelengths that can be better or more efficiently utilized by the PV device; for example, one or more red-shifting elements that perform red-shift for Ultra Violet (UV) or blue wavelengths. Such layer(s) may be colored with a coloring agent, for aesthetic or ornamental purposes or for other reasons, or to otherwise integrate the relevant layer(s) to the surface of the article to which such layer(s) are attached or to regions of the article that are located nearby.

Some embodiments provide methods and systems for producing an article, and particularly an article formed exclusively or dominantly of rubber or raw rubber or recycled rubber; by performing one or more rubber injection molding and/or rubber compression molding and/or rubber transfer molding process(es), such that the solar cell or solar panel or other PV device is inserted or added or placed as an “insert” item, before or during such rubber molding process, and becomes integrally integrated or embedded or incorporated in the rubber-based article during the rubber molding process; without a subsequent need to perform a gluing step or a screwing of screws step or other mechanical connection step between the PV device and the nearby rubber region; and such that the rubber molding itself, upon cooling down of the article, causes the solar panel or PV device to be integrally embedded and/or connected and/or attached and/or held in place within or on a rubber surrounding or a rubber region of the finished article.

Some embodiments provide methods and systems for performing rubber injection molding and/or rubber compression molding and/or rubber transfer molding process(es), utilizing and/or incorporating and/or placing and/or inserting in the rubber molding process a PV device or solar panel or solar cell.

In some embodiments, the PV device or solar cell or solar panel is a rigid and non-flexible; or, is flexible; or, is semi-rigid and/or semi-flexible, or, is partially-rigid and/or partially-flexible; or, has an increased resilience to mechanical shocks and forces, and/or has an increased capability to absorb and/or dissipate mechanical shocks and forces.

In some embodiments, the PV device or solar cell or solar panel is planar, or is flat, or is a flat surface, or has a flat surface; in other embodiments, it is non-planar, or is curved or concave or convex, or has a three-dimensional structure other than a flat surface; or is structured to have one or more planar regions or surfaces and also one or more non-planar regions or surfaces.

In some embodiments, particularly when non-flat or non-planar structures or contours are used, the PV device or solar cell is flexible or semi-flexible, and/or is foldable and/or rollable, in order to increase the ability of the PV device or solar cell to endure the stress(es) which may be encountered during the rubber molding process, and/or to allow the PV device or solar cell to modularly adapt to a non-flat or non-planar region of the mold or the molding system.

In some embodiments, the manufacturing process may include attaching one or more PV devices to a surface of a mold; or placing, or mounting, or inserting, or holding in place, such one or more PV devices onto a surface of a mold; or otherwise inserting one or more PV devices into a rubber molding system or into a rubber molding machine or into a rubber-producing mold, such that the PV device(s) are positioned in a manner and/or at a location that allows the rubber molding process to be performed while such PV device(s) are within the rubber molding machine or the rubber molding system. Then, the method includes performing rubber injection molding or rubber compression molding or rubber transfer molding, of one or more rubber material(s) and/or raw rubber material(s) and/or recycled rubber material(s), over the placed PV device(s); such that the molten elastomer of the rubber attaches to (and/or directly surrounds and/or directly touches and/or directly holds in place and/or directly secures in place) the pre-placed PV device(s); and such that the rubber molded article and the PV device(s) become integral parts of the same, single, finished rubber-based article.

In some embodiments, the molten rubber elastomer is routed during the rubber molding process through particular routing paths within the rubber molding machine or system, and/or through the mold itself and/or by using particular and pre-configured cavities for passage (or for selectively blocking) molten rubber or molten elastomer; to ensure that the molten rubber or molten elastomer would surround and/or hold and/or touch the PV device(s), and/or would create a border or frame around the PV devices; yet would not cover or would not obstruct the active surface (the “sunny side”) of the PV device that is configured to absorb light which is then converted to electricity via the PV effect.

In other embodiments, the PV device may be entirely encapsulated and entirely surrounded, from all 360 degrees around it, by molten rubber and/or molten elastomer, as such molten elastomer or molten rubber (or, the formed rubber after it cools down) are transparent and/or translucent and/or allow partial or full passage of light or sunlight therethrough; thereby maintaining the PV capability of the PV device even though it is partially or entirely surrounded or encapsulated or held by such rubber or elastomer.

In some embodiments, a plurality of such PV device(s) are electrically connected to each other, in parallel and/or in series and/or via a particular electrical circuit structure, to aggregate or accumulate or collect or build-up electric current and/or electric voltage. In some embodiments, two or more such PV devices are pre-connected to each other, electrically, prior to their placement as an “insert” in the rubber molding machine or in the mold; and they remain electrically connected through and during and also after the rubber molding process. In other embodiments, two or more such PV devices are not electrically pre-connected to each other, prior to their placement as an “insert” in the rubber molding machine or mold; but rather, they are placed as two or more separate “insert” items; and only after the rubber molding process is performed, and optionally after cooling down of the molded rubber article, the two or more PV devices are electrically connected to each other, e.g., via wires, cables, conductors, electrodes, or the like; which may be soldered or glued or bonded to conducting points or conducting regions or to electrodes of such PV device(s).

In some embodiments, the single PV device that is inserted, or at least one of a series or a set or an array or an arrangement of such multiple PV devices, may end or terminate with at least one set or one pair of terminals or electrodes, enabling to connect the PV device(s) to an external device (e.g., an external device that consumes and/or stores the PV-generated electricity).

In some embodiments, for example, the molded rubber-based article may be a box or a container, or a cover or a protective cover for a box or a container or for another device or for an electronic device, or a floating device, or a part of a boat or marine vessel, or a part of a road sign or a bollard or traffic light or a traffic control box, or a part of a roof, or a roof-tile or shingle or roof-shingle or tile, or a part of rubber-based carpet or carpeting or floor or floor-element or floor tile, or a part of other rubber-based device or apparatus or component.

In some embodiments, the PV device may be a set or array or matrix or series or solar panels or PV modules, that are integrally embedded or incorporated in a roof or ceiling or wall or panel or a house or a vessel or a vehicle or an aircraft or a container or shack or shed or toolshed; and the PV-generated electricity that is generated by such PV device is transferred via electrodes or wires or cables to a rechargeable battery or a rechargeable power cell that is located within the article or nearby, or is transferred to an appliance or device that consumes such PV-generated electricity or that transports it further to another electricity consuming device or electricity storage device.

In some embodiments, the one or more PV devices are manually and/or mechanically placed or mounted or held in the mold of the rubber molding machine, or within the mold or adjacent to the mold of the rubber molding machine; and are optionally held in place (e.g., temporarily, prior to and/or during the rubber molding process itself) by vacuum, and/or by adhesive or glue, and/or by mechanical anchoring, and/or via other connection method or mounting method or placement method or holding method prior to introducing the molten elastomer or the molten rubber to the mold.

In some embodiments, the rubber injection molding that is used may be, for example, screw-based or ram-based rubber injection molding, e.g., that uses a screw or a ram or other component as a plunger to push or to force the molten elastomer or the molten rubber into the mold cavity.

In some embodiments, optionally, the elastomer or the rubber or raw rubber or recycled rubber may include one or more foaming agents or foaming materials or foam-creating agents or foam-inducing agents or blowing agents, or chemical blowing agents (e.g., isocyanate; or isocyanate and water; or azodicarbonamide; or hydrazine or nitrogen-based materials; or sodium bicarbonate); for example, in order to reduce the density of the finished rubber-based article, and/or to reduce or absorb or dissipate mechanical stresses or shocks or forces in the rubber molded article, and/or in order to increase floating capability or buoyancy properties of the rubber molded article, and/or to assist in creating a lightweight rubber-molded article, or for other purposes.

In some embodiments, the rubber or raw rubber or recycled rubber, or the raw materials that are fed into the rubber molding machine, consist exclusively of rubber and/or elastomers; and lack, or exclude, or do not include, any non-elastomer polymer, or any non-elastomer polymers, or any non-rubber polymers, or any non-elastomer plastic materials, or any non-rubber plastic materials, or any non-rubber materials. This may ensure, for example, that the final article is indeed elastic, or has a particular or desired or pre-defined level of elasticity or flexibility; rather than becoming a rigid or semi-rigid plastic article. Similarly, in some embodiments, the final article that is produced, and which includes rubber regions as well as one or more integrated PV device(s), is a finished article that consists exclusively of rubber and/or elastomers (and the PV device(s)); and lack, or exclude, or do not include, any non-elastomer polymer (other than the PV device(s)), or any non-elastomer polymers (other than the PV device(s)), or any non-rubber polymers (other than the PV device(s)), or any non-elastomer plastic materials (other than the PV device(s)), or any non-rubber plastic materials (other than the PV device(s)), or any non-rubber materials (other than the PV device(s)).

In some embodiments, the PV device(s) are placed or held or mounted on, or at, or adjacent to, a planar or flat area or region of the mold of the rubber molding machine. Additionally or alternatively, in some embodiments, the PV device(s) are placed or held or mounted on, or at, or adjacent to, a non-planar or non-flat or curved or contoured or convex or concave area or region of the mold of the rubber molding machine. In some embodiments, one or more PV devices are placed or held on (or at) a planar or flat region of the mold of the rubber molding machine; and also, one or more other PV devices are placed or held on (or at) a non-planar or non-flat or curved region of the same mold of the rubber molding machine.

In some embodiments, a solar cell or a solar panel or a PV device has two surfaces or two sides: (A) a first surface or a first side, which is denoted as a “sunny surface” or “sunny side”, or as “light-absorbing surface” or as “light absorbing side”, or as “light-facing surface” or “light-facing side”; which is the side or the surface that is intended to be facing sunlight or the sun or a light source, or which is the side or the surface that is configured to absorb sunlight or light and to convert such absorbed light into electric charge(s) or electricity or electric current or electric voltage; and also, (B) a second surface or a second side, which is denoted as a “non-sunny surface” or “non-sunny side”, or as a “dark surface” or “dark side”, or as “non light-absorbing surface” or as “non light-absorbing side”, or as “non light-facing surface” or “non light-facing side”; which is the side or the surface that is intended not to be facing sunlight or the sun or a light source, or which is opposite to and/or directed away from the “sunny side”, or which is the side or the surface that is not configured to absorb sunlight or light for conversion into electric charge(s) or electricity or electric current or electric voltage. In some embodiments, a solar cell or a solar panel or a PV device is thus uni-facial or is single-facial or is one-sided, such that it can absorb light and convert it to electricity only via its “sunny side” and not via its “dark side”.

In other embodiments, a solar cell or a solar panel or a PV device has two surfaces or two sides; wherein each one of them is, or can be seen as, or is configured to be operable as, a “sunny side” or a “sunny surface”, facing away from each other towards opposite directions; such that the solar cell or solar panel or PV device is a bi-facial or double-facial or dual-facial, or is double-sided or double-facial, such that it can absorb and/or transfer light and convert it to electricity via each one of its two opposite surfaces or two opposite sides. Such double-sided PV device may be suitable for situations in which sunlight or light is expected or intended to reach the PV device from two or more directions, or from a direction that is not perpendicular to one of the surfaces of the PV device; for example, in a PV device that is intended to be installed generally perpendicular to the ground and may thus absorb sunlight or light from both of its sides at different times of the day, or in a PV device that is intended to be moving or rotating or spinning or otherwise changing its spatial orientation due to movement or due to other reasons.

In some embodiments, the PV device is placed or mounted or held such that its “sunny side” (the active solar material that absorbs the light and converts it to electricity) is facing the mold of the rubber molding machine, or is facing towards the mold of the rubber molding machine. In other embodiments, the PV device is placed or mounted or held such that its “sunny side” (the active solar material that absorbs the light and converts it to electricity) is facing away from the mold of the rubber molding machine.

In some embodiments, the PV device is placed or mounted or held such that its “dark side” (the non-active side) is facing the mold or is facing towards the mold of the rubber molding machine. In other embodiments, the PV device is placed or mounted or held such that its “dark side” (the non-active side) is facing away from the mold of the rubber molding machine.

In some embodiments, a dual-sided or double-sided PV device may be used, such that one “sunny side” thereof is facing the mold of the rubber molding machine, and another “sunny side” thereof is facing away from the mold of the rubber molding machine.

In some embodiments, the molten rubber and/or the molten elastomers are transparent and/or translucent and/or clear, and/or allow at least partial passage there-through of light or sunlight. Additionally or alternatively, the solidified elastomer(s), or the solidified rubber material(s), are transparent and/or translucent and/or clear, and/or allow at least partial passage there-through of light or sunlight. This may allow, for example, partial or even complete encapsulation of the PV device by molten rubber and/or molten elastomer(s), which then cool down and/or solidify into transparent or semi-transparent or partially-transparent or translucent or clear layer(s) of rubber or elastomer; and thereby providing a finished article in which the solar cell or the PV device is tightly and securely held in place, or is even “buried” or contained or sandwiched within the finished rubber or rubber-based article (e.g., for increased protection against mechanical shocks), yet the PV device is operational and operable since the transparent or translucent or clear elastomer layer(s) and/or rubber layer(s) allows passage of light there-through and the light reaches the active side(s) or the “sunny side(s)” of the PV device which generate electricity. Some embodiments may utilize clear and/or transparent and/or translucent rubber or raw rubber or recycled rubber; for example, as non-limiting examples, strips or pieces or cuts of clear transparent silicone rubber products that are available from “Auto marine Products Inc.” of San Diego, California, USA (available at: <AeroMarineProducts.com>); or strips or pieces or cuts of clear transparent silicone rubber sheets that are available from “Shenzhen Laimeisi Silicone Industry Co., Ltd.” of Guangdong, China (available at: <laimeisi.en.alibaba.com>); or strips or pieces or cuts of clear rubber available from “Smooth-On, Inc.” of Macungie, Pennsylvania, USA (available at: < smooth-on.com>); and/or other suitable clear or transparent or translucent rubber materials or scrap rubber or recycled rubber.

In some embodiments, the molded rubber-based article may be, for example, a box or container, a coating or a protective case or a protective element for a box or a container; a part or a portion of a cooler box or cooler container (e.g., for camping) or ice chest or drinks cooler box or picnic box, or a part of a storage unit, or a part of a mobile home, or a part of a shed or shack or toolshed or storage shed; and the PV device(s) may be an integrated part of a component or a cover or a coating or a rubber-made element of sch article.

In some embodiments, the molded rubber-based article may be, for example, a roof, or a shingle, or a roof segment, or a roof cover, or a roof tile, or a structure that is intended to cover another object (e.g., to cover a vehicle, or to cover a marine vessel or an aircraft, or to cover a parking spot or a parking lot), or a pergola, or an awning, or a shade structure; and the PV device(s) may be an integrated part of such rubber-based article.

In some embodiments, the molded rubber-based article having the PV device integrated therein may be, for example, an article that is intended to cover or to protect, entirely or partially, or to be mounted on, a vehicle, a car, a truck, a bus, a train, a train car or train wagon, a motorcycle, a boat, a yacht, a drone, an airplane, an airplane, a marine vessel, a self-driving vehicle, a bicycle, an electric bicycle, or a transportation device; and the PV device(s) may be an integrated part of such article; and the rubber-based article may be molded or formed based on, or to accommodate, the three-dimensional contour or structure or shape of such object that is intended to be covered or protected; or, the rubber-based article may be molded according to the contour of such existing object or vehicle (or its roof, trunk, hood, or other region) and may be placed on top of (or may be attached to) such object or vehicle or roof.

In some embodiments, the molded rubber-based article having the PV device integrated therein may be, for example, a vehicular rubber article; for example, a bumper, “fender bender” protective element, a rear-side bumper, a front-side bumper, a plastic roof-top mounting unit (e.g., for connecting bicycles or items on top of a vehicle), a back-side mounting unit (e.g., for connecting bicycles or items behind a vehicle), a vehicular roof cover or roof-segment cover (e.g., particularly when portions of the roof are formed of fabric or rubber; such as, a roof of a convertible car, or a roof of a club cart or a golf cart), or the like.

In some embodiments, the molded rubber-based article having the PV device integrated therein may be, for example, a protective cover or a protective case or a protective sleeve or a protective jacket for: an electronic device, an Internet of Things (IoT) device or sensor, an Internet-connected device, a home appliance, an electronic device capable of wireless communication and/or cellular communication, a smartphone, a housing for a smartphone, a tablet, a housing for a tablet, a smart-watch, a housing for a smart-watch, a laptop computer, a housing for a laptop computer, a desktop computer, a gamine device, a gaming console, an Augmented Reality (AR) device or helmet or gear, a Virtual Reality (VR) device or helmet or gear, a housing for a desktop computer, a security camera or an Internet-connected camera, a housing for a security camera or for an Internet-connected camera, or the like.

In some embodiments, the molded rubber-based article having the PV device integrated therein may be structured and/or configured to have a sufficiently-low density to enable the article to float on water or on sea water or on lake water or on sweet water; thereby enabling to produce, for example, a floating object, a floating device, a buoy, a float, or other floating structures.

In some embodiments, optionally, the molded rubber-based article is structured or produced or shaped such that the PV device(s) are placed in one or more recessed areas or recessed regions of the article, or in inwardly-facing craters or valleys. In some embodiments, the boundaries between or among such recessed areas or craters, may be sufficiently high and/or may be sufficiently close to each other, to allow a person to walk upon the article or to allow a vehicle to drive upon the article, with no contact or with minimal (and/or temporary) contact between the person’s foot (or the vehicle’s tires) with the PV device(s), thereby preventing or minimizing damage to such PV devices, and thereby enabling the PV-based generation of electricity within a sidewalk, a road, a bridge, or other structure.

The terms “PV device” or “PV unit” or “PV module” or “solar cell” or “solar panel” may be used interchangeably.

In accordance with some embodiments, the molded rubber-based article and the PV device(s) that are integrally embedded therein are a single, monolithic, article. For example, the PV device(s) cannot be removed or un-screwed or un-glued or detached from the molded rubber that surrounds them and/or that holds them, without damaging or cracking the PV device(s) themselves and/or the surrounding rubber, and/or without deforming or cracking at least a portion of the surrounding rubber. The term “monolithic” as used above and/or herein, particularly with reference to the final rubber-based article or the molded rubber-based article, indicates (for example) that it is a single article, a singular article, an entire article, an article that is not composed of two or more detachable components; an article whose components cannot be efficiently (or at all) un-glued or un-bonded or un-screwed from each other, or separated from each other without breaking or cracking or damaging at least one component or one region of the article; an article in which the PV device is directly attached to molded rubber and/or molded elastomers via the molding itself or via the molded result itself, or via a molded solidified seamless connection that is formed by the rubber material(s) or elastomer material(s) surrounding and/or encapsulating and/or engulfing the PV device from at least some of its sides or panels; or an article that is uniform and singular such that the PV device is integrally and uniformly integrated within or embedded within or incorporated within the solidified previously-molten or previously-melted rubber and/or elastomer; or an article in which the PV device is non-detachably attached to its immediate and/or surrounding and/or adjacent regions that are formed of molded rubber and/or elastomer; or an article in which there is absolutely no gap or no air gap or no space between the PV device and the molded rubber / elastomer regions of the article that are immediately bordering and touching the PV device; or an article that is not assembled from two discrete components (a rubber based body, and a PV device) that are mechanically glued or screwed together, but rather, the PV device is held in place via its direct contact with the molded rubber and/or elastomer that solidified and hardened immediately adjacent to it. In accordance with some embodiments, there does not exist an already-prepared “rubber body”, to which a PV device is later screwed or glued; but rather, the rubber body or the rubber-based article is created simultaneously with, or concurrently with, or at the same time with, and/or via the same single operation of, molding the raw rubber material(s) or the raw elastomers to create, at the same time, the rubber article and the molded rubber-based “connection” that integrally connects or holds the PV device to is concurrently-solidified surrounding rubber or elastomer.

In some embodiments, rubber or recycled rubber or scrap rubber may undergo a process which causes it to melt, or to become molten, or to become almost-molten or almost-melted, or to have a state that allows the rubber to flow similar to flow of a liquid rather than being non-flowing like a solid, or to have a state that allows the rubber to shape-shift and/or to modify its three-dimensional structure or its spatial structure and to assume or obtain a structure of a surrounding mold or template or enclosure or container. In some embodiments, the rubber or scrap rubber may be heated up to reach its melting point or its melting temperature (e.g., typically in the range of 260 to 316° C.), such that molten rubber or melted rubber is then injected or transported or transferred into a mold or a template and can then assume or obtain the three-dimensional structure or spatial shape of the inner side or the inner cavity of such mold or template, and may cool-down and solidify and harden therein. In some embodiments, the rubber need not necessarily be entirely molten or entirely melted, in order to be transferred into such mold or mold cavity template, and/or in order to flow towards or into such mold or mold cavity or template, and/or in order to achieve chemical and/or mechanical properties that enable such heated-up (yet not necessarily molten) rubber to flow and/or to shape-shift. In some embodiments, non-vulcanized rubber or non-vulcanized scrap rubber or non-crosslinked rubber or non-crosslinked scrap rubber may be used, to facilitate or to hasten the melting of rubber, or to achieve molten rubber at a lower heating temperature. In some embodiments, vulcanized rubber or vulcanized scrap rubber may be used; and optionally, a higher temperature may be used for heating and/or melting such rubber. In some embodiments, a mixture of vulcanized and non-vulcanized rubber (or scrap rubber) may be used.

The Applicants have also realized that some particular types of vulcanized rubber or otherwise cross-linked rubber, may not necessarily transform (partially, or entirely) into a molten state, even if exposed to heating at very high temperature; but rather, may instead undergo thermal degradation if exposed to such high-temperature heating. However, the Applicants have realized that in some embodiments, even such types of vulcanized rubber or otherwise cross-linked rubber or non-melting rubber, may still be ground or cut or chopped or sliced into small particles or small pellets or small granules, and may still be added as fillers or as filling agents or filler agents in the rubber-based article that integrally incorporates a PV device thereon or therein (as well as in similar plastic-based articles).

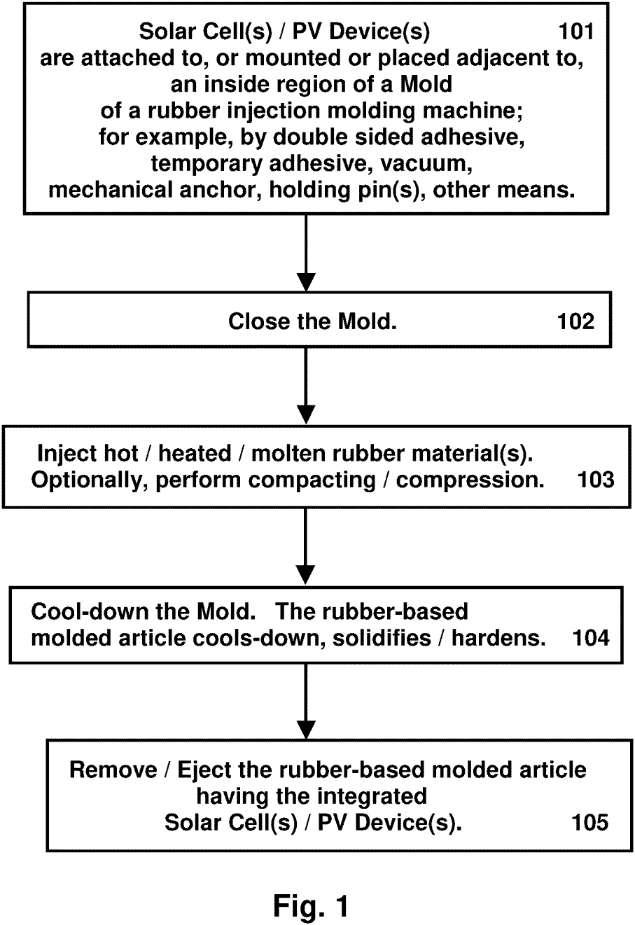

Reference is made to FIG. 1, which is a flow-chart of a method of producing via injection rubber molding a rubber-based or elastomeric article having one or more integrated PV device(s), in accordance with some embodiments.

In accordance with some embodiments, innovatively, surprisingly, and counter-intuitively, a fully operable PV device, which is an Actively Functional electric device that generates electric power from absorbed light, is incorporated or embedded in the mold of a rubber molding machine and/or in the rubber molding process and/or the rubber molding machine; and surprisingly, and counter-intuitively, the PV device remains operable and/or operational and/or functional, even though it may be exposed to or may be subject to heat and/or high temperature and/or pressure and/or compression during the rubber molding process; and the PV device, in its post-molding state, remains operational and functional, either in its entire capacity as it was prior to the rubber molding process, or at least in a partial capacity that is still useful and sufficient for the particular purpose(s) of that PV device and/or that molded rubber-based article (or another device that consumes or that stores the PV-generated electric energy).

As indicate in block 101, one or more Solar Cell(s) or PV Device(s) are attached to, or mounted or placed adjacent to, an inside region of a Mold of a rubber injection molding machine or system; for example, by double sided adhesive, temporary adhesive, vacuum, mechanical anchor, holding pin(s), other means.

As indicated in block 102, the Mold of the rubber molding machine is closed.

As indicated in block 103, hot rubber material(s) and/or hot molten elastomer(s) and/or pre-heated rubber material(s), are injected. Optionally, compacting and/or compression operations are performed on the rubber / elastomer materials within the mold.

As indicated in block 104, the Mold of the rubber molding machine is then cooled down; and the molded rubber-based article hardens and/or solidifies and/or assumes its final shape and structure.

As indicated in block 105, the method includes removing or ejecting the injection-molded rubber article having the integrated Solar Cell(s) / PV Device(s). For example, the Solar Cell(s) / PV Device(s) are integrally incorporated in, or on, or as part of, a particular region of an external layer or external side of the injection molded rubber-based article.

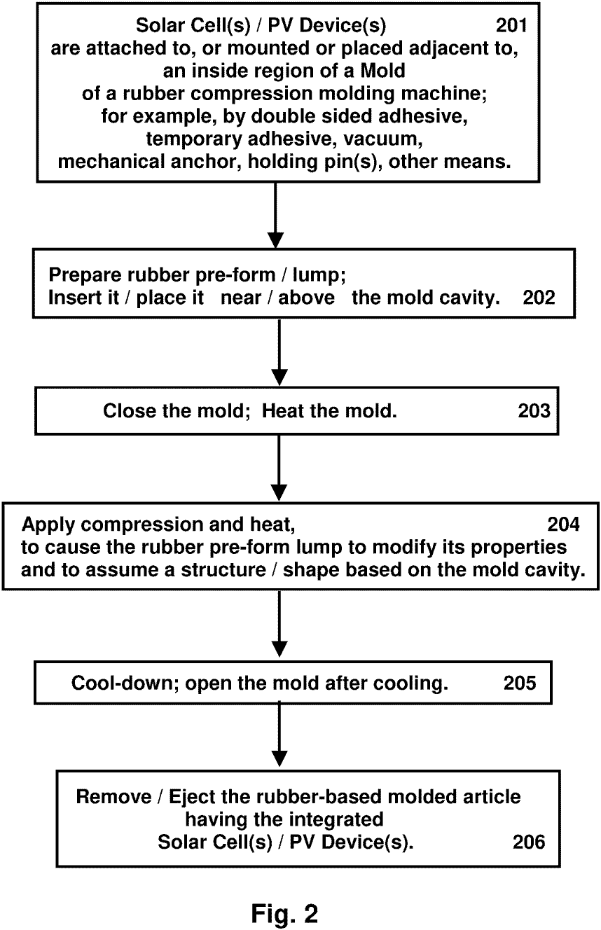

Reference is made to FIG. 2, which is a flow-chart of a method of producing via compression rubber molding a rubber-based or elastomeric article having integrated PV device(s), in accordance with some embodiments.

In accordance with some embodiments, innovatively, surprisingly, and counter-intuitively, a fully operable PV device, which is an Actively Functional electric device that generates electric power from absorbed light, is incorporated or embedded in the compression rubber mold and/or in the compression rubber molding process and/or the compression rubber molding machine; and surprisingly, and counter-intuitively, the PV device remains operable and/or operational and/or functional, even though it may be exposed to or may be subject to heat and/or high temperature and/or pressure and/or compression during the rubber compression molding process; and the PV device, in its post-molding state, remains operational and functional, either in its entire capacity as it was prior to the rubber molding process, or at least in a partial capacity that is still useful and sufficient for the particular purpose(s) of that PV device and/or that rubber-based molded article (or another device that consumes or that stores the PV-generated electric energy).

As indicate in block 201, one or more Solar Cell(s) or PV Device(s) are attached to, or mounted or placed adjacent to, an inside region of a Mold of a rubber compression molding machine or system; for example, by double sided adhesive, temporary adhesive, vacuum, mechanical anchor, holding pin(s), other means.

As indicated in block 202, a rubber compound or a rubber pre-form is prepared; such as, from rubber or recycled rubber or scrap rubber; for example, in the form of a rubber block or a rubber chunk or a rubber aggregate, or a recycled rubber block or a recycled rubber chunk or a recycled rubber aggregate. The pre-formed rubber (or recycled rubber, or scrap rubber) lump or chunk, introduced or inserted into the mold of the rubber compression molding machine; and particularly, is placed over or above or near or adjacent to, or within, a cavity of that mold of the rubber compression molding machine. For demonstrative purposes, a single rubber chunk or rubber lump is discussed as being placed at or within or above or near a single cavity of the mold; however, in some embodiments, two or more such separate rubber chunks or lumps may be placed at or within or above or near two or more (respective) cavities of that same mold.

As indicated in block 203, the method includes closing the mold of the rubber compression molding machine; thereby causing the pre-formed rubber chunk(s) or lump(s) to be trapped or enclosed or sandwiched within the two parts of the mold, and become subject to mechanical compression. The method further includes heating the mold, or applying heat to the entirety of the mold or at least to a region of the mold that includes the relevant mold cavity at which the pre-formed rubber chunk or lump was placed.

As indicated in block 204, apply compression and heat to cause the pre-formed rubber chunk or lump to melt (entirely or partially) and/or to modify its physical properties and/or mechanical properties and/or chemical properties, and cause it to assume the shape or structure or form or spatial structure or three-dimensional structure of the mold cavity of the rubber compression molding machine. Optionally, a portion of the rubber material from the original pre-formed rubber chunk or rubber lump, may be an excess portion which may spill over to one or more rubber overflow grooves or excess rubber receiving grooves or craters or channels.

As indicated in block 205, the mold of the rubber compression molding machine is cooled down, the rubber-based molded article hardens and solidifies, and the mold is opened to allow removal of the article therefrom.

As indicated in block 206, the method includes removing or ejecting the rubber-based compression-molded article having the integrated Solar Cell(s) / PV Device(s). For example, the Solar Cell(s) / PV Device(s) are integrally incorporated in, or on, or as part of, a particular region of an external layer or external side of the rubber-based compression molded article.

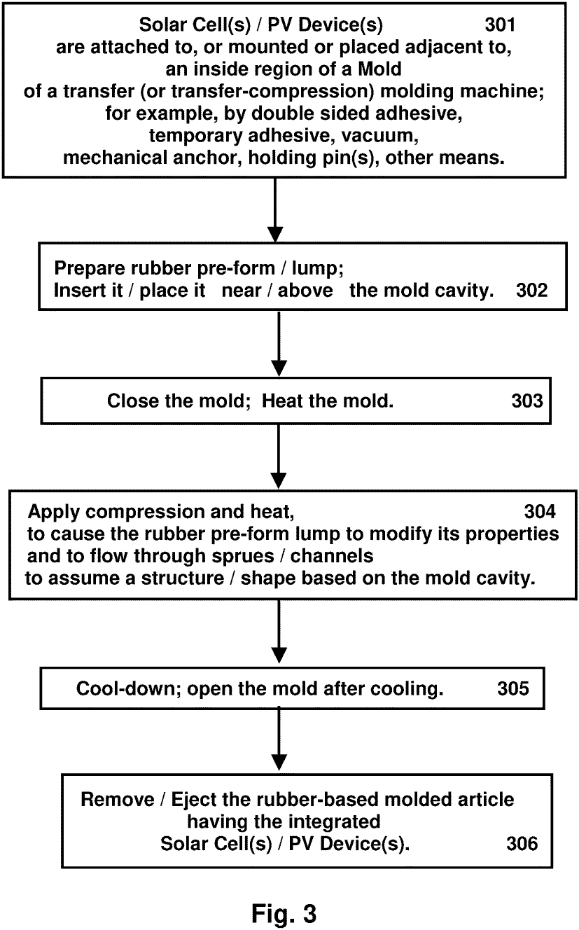

Reference is made to FIG. 3, which is a flow-chart of a method of producing, via rubber transfer molding (or, via rubber transfer-compression molding), a rubber-based or elastomeric article having integrated PV device(s), in accordance with some embodiments.

In accordance with some embodiments, innovatively, surprisingly, and counter-intuitively, a fully operable PV device, which is an Actively Functional electric device that generates electric power from absorbed light, is incorporated or embedded in the transfer rubber mold and/or in the rubber transfer molding process and/or the rubber transfer molding machine; and surprisingly, and counter-intuitively, the PV device remains operable and/or operational and/or functional, even though it may be exposed to or may be subject to heat and/or high temperature and/or pressure and/or compression during the rubber transfer molding process; and the PV device, in its post-molding state, remains operational and functional, either in its entire capacity as it was prior to the rubber transfer molding process, or at least in a partial capacity that is still useful and sufficient for the particular purpose(s) of that PV device and/or that rubber-based molded article (or another device that consumes or that stores the PV-generated electric energy).

As indicate in block 301, one or more Solar Cell(s) or PV Device(s) are attached to, or mounted or placed adjacent to, an inside region of a Mold of a rubber transfer molding machine or system; for example, by double sided adhesive, temporary adhesive, vacuum, mechanical anchor, holding pin(s), other means.

As indicated in block 302, a rubber compound or a rubber pre-form is prepared; such as, from rubber or recycled rubber or scrap rubber; for example, in the form of a rubber block or a rubber chunk or a rubber aggregate, or a recycled rubber block or a recycled rubber chunk or a recycled rubber aggregate. The pre-formed rubber (or recycled rubber, or scrap rubber) lump or chunk, introduced or inserted into a suitable pot or pot region that is located between the two parts of the mold of the rubber transfer molding machine; the pot is located, generally, above or near a cavity of that mold of the rubber transfer molding machine. For demonstrative purposes, a single rubber chunk or rubber lump is discussed as being placed in a single pot above a single cavity of the mold of the rubber transfer molding machine; however, in some embodiments, two or more such separate rubber chunks or lumps may be placed at or within two or more (respective) pots that may be located above or near two or more (respective) cavities of that same mold; or, a single pre-formed rubber chunk or rubber lump or rubber aggregate, may be placed within or at a single unified pot that is located between the two parts of the mold of the rubber transfer molding machine, and that single pre-formed rubber chunk and that single pot subsequently feed molten and compressed rubber into two or more cavities within the mold, via two or more (respective) channels or sprues.

As indicated in block 303, the method includes closing the mold of the rubber transfer molding machine; thereby causing the pre-formed rubber chunk(s) or lump(s) to be trapped or enclosed or sandwiched in the pot within the two parts of the mold, above or near the one or more mold cavities, and become subject to mechanical compression. The method includes heating the mold, or applying heat to the entirety of the mold or at least to a region of the mold that includes the pot with the pre-formed chunk of rubber.

As indicated in block 304, compression and heat are applied, to cause the pre-formed rubber chunk or lump to melt (entirely or partially) or to change its physical properties and/or chemical properties and/or mechanical properties; and one or more sprue(s) or channels or molten rubber channels cause the molten or modified or heated rubber to flow from the pot area to one or more mold cavities of the rubber transfer molding machine; and cause it to assume the shape or structure or form or spatial structure or three-dimensional structure of the mold cavity of the rubber transfer molding machine. Optionally, a portion of the rubber material from the original pre-formed rubber chunk or rubber lump, may be an excess portion which may spill over to one or more rubber overflow grooves or excess rubber receiving grooves or craters or channels.

As indicated in block 305, the mold of the rubber transfer molding machine (or, the rubber transfer-compression molding machine) is cooled down; the rubber-based molded article hardens and solidifies, and the mold is opened to allow removal of the article therefrom.

As indicated in block 306, the method includes removing or ejecting the rubber-based transfer-molded article (or, the rubber-based transfer-compression molded article) having the integrated Solar Cell(s) / PV Device(s). For example, the Solar Cell(s) / PV Device(s) are integrally incorporated in, or on, or as part of, a particular region of an external layer or external side of the rubber-based transfer molded article.

Referring to the methods of FIGS. 1 and 2 and 3, optionally, a step of deflashing or deflashing may be performed, in which waste edge(s) or “flash” or excess rubber are removed from the molded rubber-based article. This may be performed, for example, manually by a person equipped with a blade or knife or trimming device who inspects finished products; and/or by a robotic device or machine, optionally equipped with a camera or imager and a computerized vision processor which may inspect the shape or contour or three-dimensional structure of the molded rubber article, may detect excess parts or imperfections, and may activate a trimming unit or a blade or knife or a laser-based cutting unit to perform precise cutting or tearing of excess rubber.

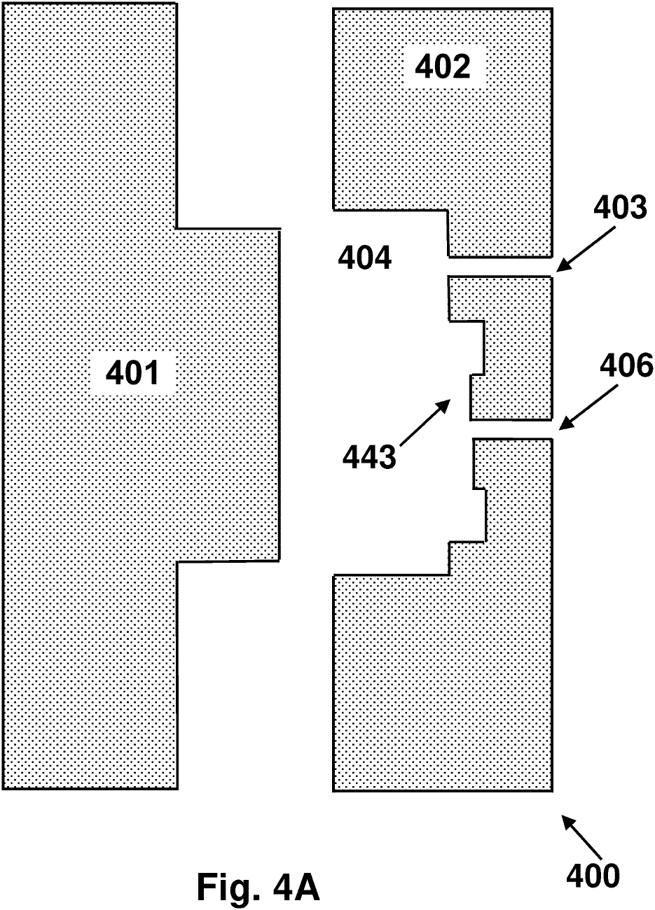

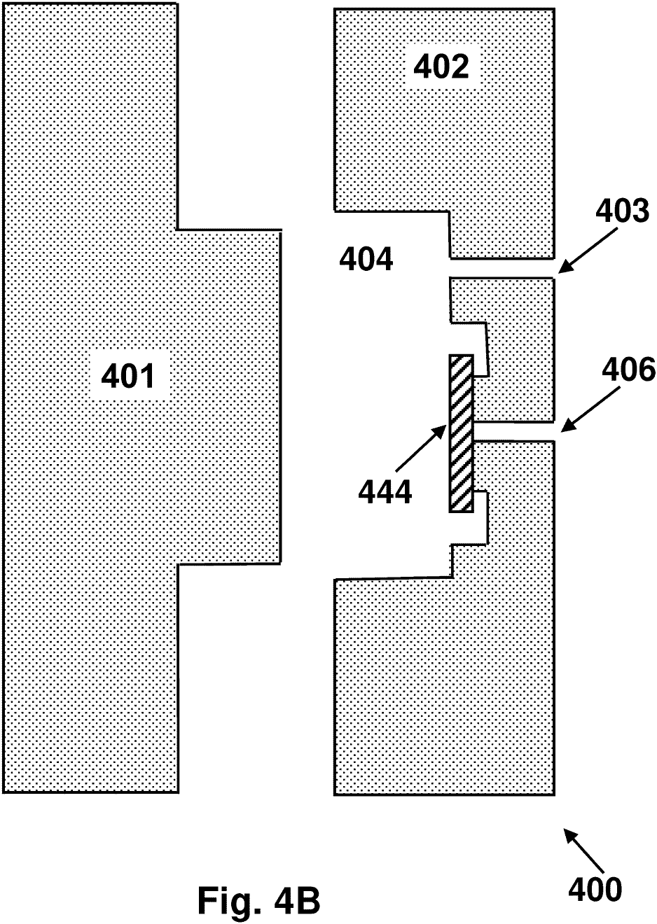

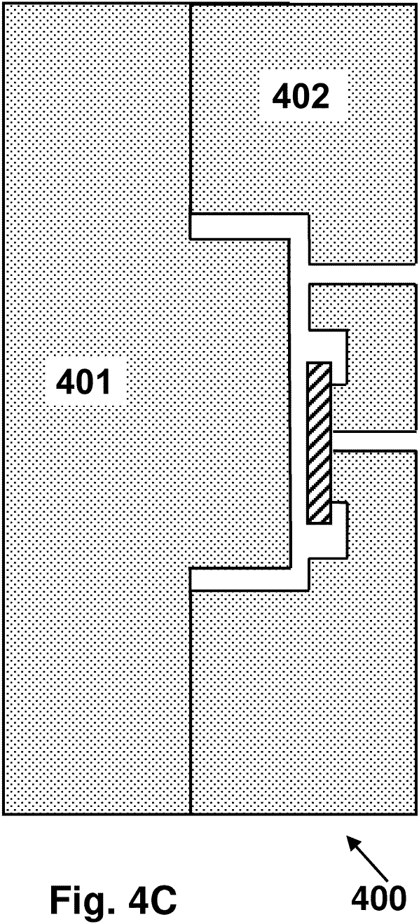

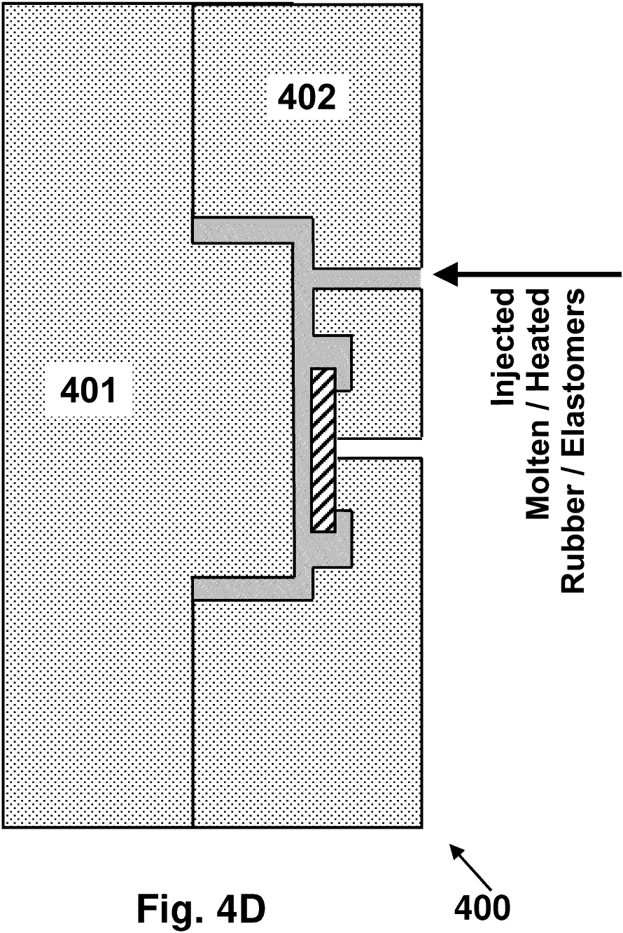

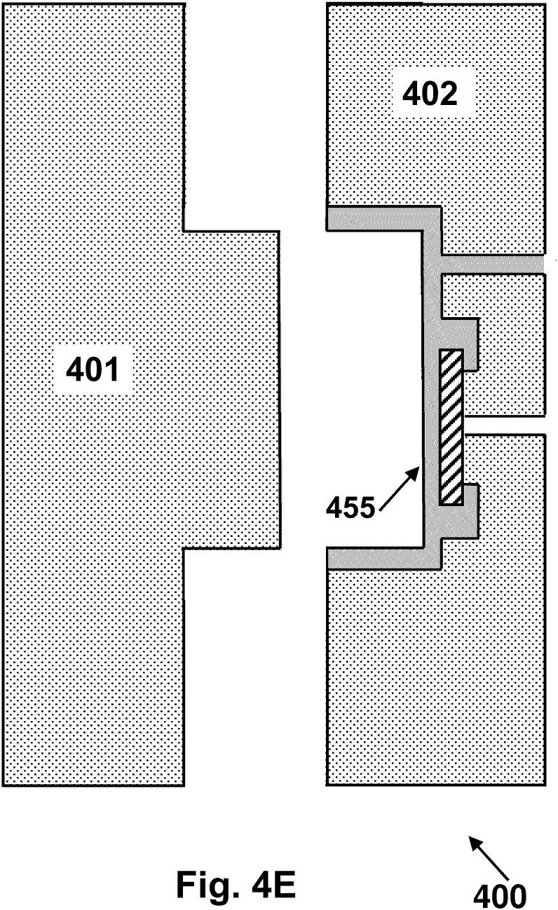

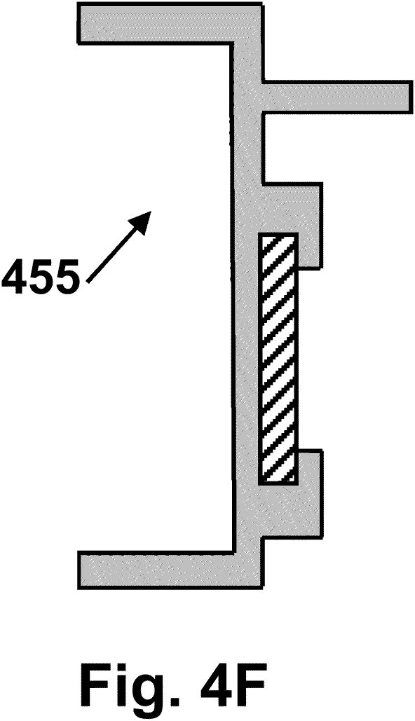

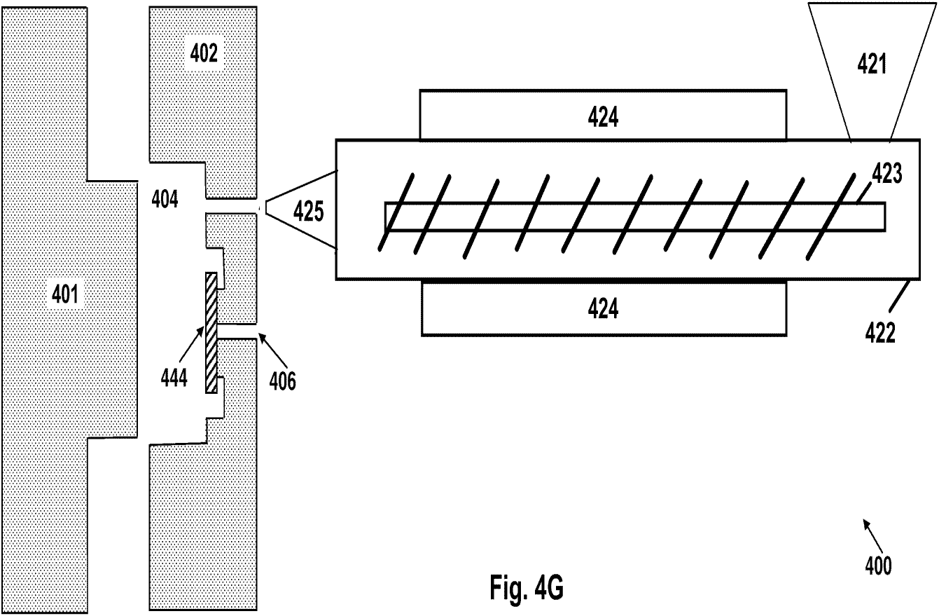

Reference is made to FIGS. 4A to 4G, which are schematic illustrations demonstrating components and operational steps of a rubber injection molding system 400, in accordance with some demonstrative embodiments. In accordance with some embodiments, innovatively, surprisingly, and counter-intuitively, a fully operable PV device, which is an Actively Functional electric device that generates electric power from absorbed light, is incorporated or embedded in the mold of the rubber molding machine and/or in the rubber molding process and/or in the rubber molding machine; and surprisingly, and counter-intuitively, the PV device remains operable and/or operational and/or functional, even though it may be exposed to or may be subject to heat and/or high temperature and/or pressure and/or compression during the rubber molding process; and the PV device, in its post-molding state, remains operational and functional, either in its entire capacity as it was prior to the rubber molding process, or at least in a partial capacity that is still useful and sufficient for the particular purpose(s) of that PV device and/or that molded article (or another device that consumes or that stores the PV-generated electric energy.

In order to focus on some particular aspects of some embodiments, and in order to not obscure the drawings, conventional components of a rubber injection molding machine are not shown, yet they can be used to achieve their respective functionality. For example, a rubber injection molding machine may include an injection unit, which performs heating and injecting of molten rubber material (e.g., rubber, raw rubber, recycled rubber, scrap rubber, rubber lumps or chunks, rubber granules or pellets or particles or strips) into a mold. The injection unit may include a hopper, which is a container that receives the rubber material(s) and/or elastomer(s); for example, as pellets, as granules, as powder, as blocks, or strips, as beads, as solid units, as lumps or chunks, or the like.

In some embodiments, optionally, the pellets or granules of rubber material(s) or elastomer(s) may comprise one or more reinforcement elements or mechanical resilience elements or mechanical support elements or mechanical reinforcing agents, such as, glass fiber, chopped glass fiber, diced glass fiber, fibers of glass, chopped or cut fibers of glass, thin strands of glass or silica-based formulations, E-glass fibers or strands (e.g., formed of alumino-borosilicate glass, typically with less than 1% w/w alkali oxides), A-glass fibers or strands (e.g., Alkali-lime glass with no boron oxide or with a negligible amount thereof), E-CR-glass fiber or strands (e.g., Electrical/Chemical Resistance glass fibers or strands; for example, alumino-lime silicate, typically with less than 1% w/w alkali oxides, with high acid resistance), C-glass fibers or strands (e.g., alkali-lime glass with high boron oxide content), D-glass fibers or strands (e.g., borosilicate glass, having a low Dielectric constant), R-glass fibers or strands (e.g., alumino silicate glass, without MgO and CaO, having high mechanical reinforcement properties), S-glass fibers or strands (e.g., alumino silicate glass, without CaO but with high MgO content, providing high tensile strength), mica, mica crystals, mica fibers or strands, crystallized phyllosilicate mineral(s), and/or other suitable reinforcement agents or materials.

A bottom opening of the hopper transfers, or feeds, the raw rubber material(s) into a barrel, which includes the mechanism for heating and injecting the material into the mold of the rubber molding machine. A plunger or a reciprocating screw or a rotating screw or a ram injector or other suitable injection member or extruder (e.g., using electric motor or hydraulic motor) moves or pushes or advances the material(s). A heating unit or multiple heaters surround (or are adjacent to) the barrel-region or the channel through which the material(s) advance, and provide to them heat. The advancing material(s) melt and/or change their chemical properties and/or change their physical properties due to the heat, and optionally also due to pressure and compression and friction which contribute to such melting or properties modification. The molten or modified rubber material(s) are injected (e.g., rapidly) into the mold of the rubber molding machine, through an injection nozzle and via a die or opening at the end of the barrel, using an injection force provided by the buildup of pressure and/or by the rotation of the rotating screw and/or by the push forces applied to the material(s). The injected rubber materials fill a cavity (or multiple cavities) within the mold, that is defined by particularly-structured gaps between a female member and a male member of the mold of the rubber molding machine. After the injection, the molten rubber material(s) or the heated and compressed rubber materials cool-down, and typically harden and/or solidify within the mold of the rubber molding machine, resulting in an injection-molded rubber-based article. Then, the mold of the rubber molding machine is opened, and/or the injection screw (or other injection mechanism) may be retracted; and the injection-molded rubber-based article may be released or extracted or ejected or otherwise released or removed from the mold of the rubber molding machine.

Prior to injection, or prior to entry or movement or flow or transfer of the heated rubber materials, the two members or two halves or two parts of the mold are securely closed by a clamping unit, each member affixed to a platen or a large plate. The female member of the mold may also be known as the member having the mold cavity, or as the front member or the front-side member. The male member of the mold may also be known as the rear member or the rear-side member, or as the mold core. The mold may be formed of steel or aluminum or other suitable metal(s). Optionally, multiple discrete cavities may be defined by multiple discrete gaps between the male member and the female member, and/or by the three-dimensional structure or shape or contour of those two members of the mold.

Typically, the female member of the mold is affixed to a stationary, non-moving, front-side platen that aligns with the nozzle of the injection unit (e.g., the alignment may also be aided by locating ring). Typically, the male member of the mold is mounted on or affixed to a movable platen which may slide along tie bars or rails. Molten rubber material(s) or heated rubber materials or heated elastomers enter the mold cavity via the nozzle and a sprue, and move or flow or advance through one or more channels and/or gates and/or “runners” (which may be non-heated; or in some implementations, may be heated) which carry and/or guide and/or route the molten or heated rubber material(s).

The clamping unit may be equipped with a hydraulically powered clamping motor, to actuate clamping bars and/or clamping forces that keep the mold securely closed during the actual pressurized injection of molten or heated rubber material(s) into the mold cavity, as well as during the cooling-down period that follows the injection or the flow of the heated rubber material(s). After a pre-defined time period (e.g., ten minutes), the mold of the rubber molding machine may be opened (e.g., by distancing the male member from the female member). An ejector bar or ejector pin or ejector plate or other ejection unit may be actuated to eject or release or remove or pull the solid rubber-based molded article from the mold cavity outwardly. Optionally, water-based cooling or other type of cooling may be used to hasten the cooling down; for example, by running water or cold water through cooling channels that are near or adjacent to the mold of the rubber molding machine. Optionally, the mold cavity is pre-configured to support or to enable flow of the molten or heated rubber material(s) to all the regions of the cavity that should be filled with such material(s). Optionally, a draft angle may be applied to one or more mold wall(s) or panel(s), to facilitate ejection or removal of the final article from the mold of the rubber molding machine.

In FIG. 4A, there is shown a system 400 which comprises a rubber injection molding mold having two members: a male member 401, and a generally complementing female member 402. One or more injection port(s) 403 or other suitable injection channel(s) or injection pathway(s) or injection aperture(s) are in the female member 402, to enable injection and entry of molten or heated rubber or elastomers. A mold cavity 404 is defined between (or by) the male member 401 and the female member 402, based on their particular three-dimensional structure or shape or spatial contour. The mold cavity 404 may have a single or a unified or a continuous cavity; or alternatively, a set of two or more discrete or separate cavities.

As demonstrated in FIG. 4B, a PV device 444 is placed within the mold cavity of the rubber molding machine. For example, it is placed at a particular location 443 in the mold cavity 404; for example, adjacent to (or mounted on, or adhered to, or glued to) the female member 402. Optionally, a vacuum port 406 or a vacuum channel, or a suction port or channel, may be used to provide an outwardly-directed force that pushes (via vacuum or suction forces) the PV device 444 towards an inside wall or an inside panel or an inside region of the female member 402. In FIG. 4B, there is further shown a PV device 444 that is placed within the mold cavity of the rubber molding machine.

Optionally, the PV device 444 may be temporarily held in place, on an inner-side wall or region of the female member, not necessarily using vacuum or suction forces; but rather, using adhesive(s), double-sided adhesive, temporary or short-term adhesive; or via magnetic forces (e.g., the PV device 444 may be magnetic north, and the female member of the mold may be magnetic south; or vice versa); or using a mechanical anchor or anchoring member or anchoring pin; or using a small pin or clasp; or by fitting the PV device 444 into a particular groove or crater or recess or recessed region in the female member of the mold that then holds in place the PV device 444 via friction and/or pressure.

In FIGS. 4A and 4B, the mold is in an open position, such that the two mold members 401-402 are spaced apart. In FIG. 4C, the mold is shown in a closed position, such that at least some of the internally-facing region of the male member 401, directly touches at least some of internally-facing region of the female member 402; while a cavity is still defined between (or by) the two mold members 401-402 that now touch each other, upon closure of the mold and prior to injection or flowing of molten or heated rubber material(s) or elastomer(s).

FIG. 4D shows the system, with the molten or heated rubber material(s) 408 flowing into, and filling, the mold cavity of the closed mold of the rubber molding machine. The molten or heated material(s) 408 may touch the PV device 444, or may partially cover it, or may even entirely cover or encapsulate it (e.g., if transparent and/or translucent or clear rubber material(s) are used, to still allow at least partial passage of light towards the active parts or to a “sunny side” of the PV device 444).

FIG. 4E shows the system after the mold cooled-down, and after the male member 401 was retracted or distanced from the female member 402, thereby opening the mold cavity. A solid, monolithic, rubber-based molded article 455 was created, integrally incorporating therein the PV device 444 as an integral part thereof. The PV device 444 is injection-mold connected to the other, rubber-based, regions of the article 455. FIG. 4F shows an enlarged view of the rubber-based molded article 455 as a stand-alone article, after its ejection or removal or release from the female member 402 of the mold of the rubber molding machine.

FIG. 4G shows schematically some of the above-mentioned units of system 400; for example, hopper 421 which holds raw rubber / elastomeric material(s), barrel 422, screw 423, heater(s) 424, injection nozzle and die 425.

It is noted that the drawings are not necessarily drawn to scale; rather, the size of some components is intentionally exaggerated, in order to show more clearly some particular features, structures, or functionalities of some embodiments. For example, in some embodiments, the length or the longest dimensions of PV device 444 may range from 1 centimeter to 100 centimeters; whereas the rubber injection molding system is typically a machine having a length in the range of 2 to 8 meters, although smaller rubber molding systems or machines may be used (e.g., “lab scale” machines, having a length of 50 or 100 centimeters).

In some embodiments, rubber compression molding may be used; or rubber transfer molding (or, rubber transfer-compression molding) may be used; as described above with reference to FIGS. 2 and 3.

In some embodiments, one or more primary additives may be added and used to improve the mechanical properties of the article and/or to assist in the rubber molding process. Flow modifiers may assist in the flow of heated or molten rubber or elastomers in the molten (or heated) state to achieve proper and uniform thickness distribution. Heat stabilizers may be used to prevent thermal degradation that may be induced by high temperature. Fillers may be used to increase the stiffness; and impact modifiers may be used to increase impact strength; however, the amount of such additive may need to be controlled since they may cause rough surface and/or reduced flow. Secondary additives may also be utilized to give the finished article its characteristics, such as colorants, flame retardants, and anti-static agents.

In accordance with some embodiments, the solar cell or the PV device, that is utilized as part of the rubber molding process, is a fully-prepared or fully-operational or fully-produced or readily-functional or pre-manufactured solar cell or PV device, or a freestanding or non-supported or stand-alone or autonomous or a self-contained solar cell or PV device, which is an Active Functional Device or an Active Functional electric device that directly generates electricity from absorbed light, and that is electrically connected (e.g., via wires, cables, conductors, electrodes, electric circuit) to one or more electric energy consuming units and/or to one or more electric energy storing units.

The Applicants have discovered and realized that in accordance with some embodiments, a fully-operational or fully-operable, pre-manufactured or already-prepared, solar cell or PV device, surprisingly and counter-intuitively does not melt and/or does not get damaged and/or does not get ruined and/or does not become inoperable and/or does not break apart, when it is incorporated or placed or utilized in a mold of a rubber molding machine, even if such mold is then exposed to high temperature and/or heat and/or compression and/or mechanical forces.

Surprisingly and counter-intuitively, discovered and realized the Applicants, the solar cell or PV device remains operational or operable, entirely or at least partially, or at least remains in an operational state that allows it to still produce sufficient amount of electric current and/or electric voltage and/or electric power in its post-molding state (e.g., generating and providing sufficient electric power to a power-consuming unit or device or to a power-storing unit or device), even though such solar cell or PV device has been inserted into a mold and/or a rubber molding machine, and/or even though such solar cell or PV device has been subjected to heat or high heat or high temperatures during the rubber molding process, and/or even though such solar cell or PV device has been subjected to pressure or high pressure or clamping pressure or other mechanical forces during the rubber molding process.

Innovatively, the Applicants have realized that nobody has attempted to place a fully-operational or fully-operable Actively Functional device, such as the solar cell or the PV device described above and/or herein, into a mold of a rubber molding machine, or to embed or incorporate such PV device in such high-heat and/or high-pressure rubber molding process.

In accordance with some embodiments, the solar cell or the PV device that is inserted, embedded, incorporated and/or other utilized in the rubber molding process, is formed of semiconductor material(s) such as (for example) silicon, gallium arsenide, cadmium telluride, or other material(s). The fully-operable solar cell or PV device absorbs sunlight; and due to the PV effect, free electrons and holes are created at positive / negative junctions; and such junctions are connected via electrodes or conductors or conducting circuits or wires that collect or aggregate electric charge and generate electric current and/or electric voltage. The solar cell or PV device may be, for example, a large-area or medium-area or small-area p-n junction made from silicon; a Crystalline Silicon or c-Si solar cell or PV device; a Single Crystalline Silicon or Monocrystalline silicon solar cell or PV device; a Polycrystalline Silicon or multi-crystalline silicon solar cell or PV device; an Amorphous Silicon or a-Si solar cell or PV device, or Thin-Film solar cell or PV device; a Hybrid Silicon PV solar cell or PV device (e.g., having a combination of single crystalline silicon surrounded by thin layers of amorphous silicon), and/or other suitable type of solar cell or PV device.

In some embodiments, for example, Mono-crystalline or Poly-crystalline silicon wafers are created; for example, by cutting or wire-sawing block-cast silicon ingots into wafers (e.g., each wafer having thickness in the range of 180 to 350 micrometer). In some embodiments, the wafers are lightly p-type-doped. A surface diffusion of n-type dopants is performed on a front side (the “sunny side”) of the wafer; thereby forming a p-n junction, typically located a few hundred nanometers below the surface.

Optionally, one or more anti-reflection coatings are applied, to increase the amount of light that is coupled into or absorbed by the solar cell or PV device. For example, silicon nitride may be used, or (in some implementations) titanium dioxide, due to their surface passivation properties, to prevent carrier recombination at the cell surface. For example, a coating layer (e.g., 200 to 800 nanometers thick) may be applied, using plasma-enhanced chemical vapor deposition. Optionally, the solar cell or PV device may have textured front surfaces or three-dimensional structures, that may increase the amount of light reaching the wafer.

In some embodiments, a full area metal contact is formed on the back surface (the “dark side”); and a grid-like metal contact, which includes fine “fingers” and larger “bus bars”, may be screen-printed onto the front (“sunny side”) surface using a silver paste. In some embodiments, rear side (or “dark side”) contacts are formed by screen-printing a metal paste, such as aluminum; and such contact may cover the entire rear side, or may be a grid pattern. In some embodiments, metal paste is heated at several hundred degrees Celsius to form metal electrodes in ohmic contact with the silicon. Optionally, an additional electroplating step may be used, to increase efficiency. After the metal contacts are made, the solar cells are interconnected by flat wires and/or metal ribbons, and assembled into modules or Solar Panels. Typically, a solar panel has a sheet of tempered glass on the front (the “sunny side” surface), and a polymer encapsulation on the back (the “dark side” surface).

In some embodiments, when light or sunlight strikes the solar cell (or PV device) surface, the solar cell creates charge carrier as electrons and holes. An internal field produced by junction separates some of positive charges (holes) from negative charges (electrons). Holes are swept into positive layer or p-layer; electrons are swept into negative layer or n-layer. Individual solar cells may be connected together (electrically) to thus create a PV device or PV module or Solar Module, to increase or aggregate electric current or electric voltage; typically by connecting individual solar cells in an array or Solar Array or PV array; such as, solar arrays may be connected in parallel and thus the output electric current is increases, or solar arrays may be connected in series and thus the output electric voltage is increased, or via a different type of array or circuit having one or more region(s) or solar cells that are inter-connected in parallel and/or having one or more region(s) that are inter-connected in series.

In some embodiments, the PV device includes the Solar Cell or the Solar Module, which directly converts light into Direct Current (DC) electricity; and optionally, it includes or it is connected to a battery that is charged or recharged; optionally also connected to a Solar Charge Controller which regulates voltage and/or current from solar arrays, and/or charges a battery, and/or prevents a battery from overcharging, and/or performs controlled over-discharges; and optionally utilizing an Inverter to convert DC power output of solar arrays into AC power.

In some embodiments, optionally, the solar cell or PV device may be a mechanically-resilient and/or flexible and/or rollable and/or bendable and/or foldable solar cell or PV device; for example, due to having non-transcending gaps or “blind gaps” or craters that penetrate into from 80 to 99.9 percent of the depth of the semiconductor wafer; which provide mechanical resilience, and/or enhanced ability to absorb and/or dissipate mechanical forces and/or mechanical shocks; including, but not limited to, structures and/or components as described in U.S. Patent number US 11,081,606 B2, which is hereby incorporated by reference in its entirety.

In some embodiments, optionally, the solar cell or PV device may be flexible, and/or may already be curved and/or non-flat and/or non-planar, prior to and/or during its insertion into the mold of the rubber molding machine or into the rubber molding machine; or, may intentionally become curved or non-planar or non-flat due to its insertion and/or placement into the mold of the rubber molding machine or into the molding machine; thereby allowing to produce a rubber-based molded article that integrally incorporates therein or thereon, via molding of heated or molten rubber and/or elastomer(s), such curved or non-planar or non-flat solar cell or PV device.

In some embodiments, the utilization of a solar cell or a PV device that is mechanically-resilient and/or flexible and/or rollable and/or bendable and/or foldable, may contribute to the ability of the solar cell or PV device to withstand and/or to survive, mechanically and/or thermally and/or physically and/or operably, the heat and/or pressure and/or compression that are involved in the rubber molding process or in the process that produces the rubber-based article; as some (or all) of such heat and/or pressure and/or compression forces and/or mechanical forces of the rubber molding process or the rubber-based article production process, may be absorbed and/or dissipated and/or mitigated by the particular three-dimensional structure of the solar cell or PV device, and particularly by the above-mentioned non-transcending craters or gaps or “blind gaps” that penetrate into between 80 to 99.9 percent of the depth or thickness (but not the entire 100 percent of the depth of thickness) of the semiconductor substrate or wafer of the PV device; and optionally, due to one or more filler material(s) which may fill (partially, or entirely) such non-transcending gaps or craters and which may absorb or dissipate mechanical forces and/or chemical forces and/or physical forces and/or heat and/or pressure(s) and/or compression forces and/or thermal shock and/or thermal changes.

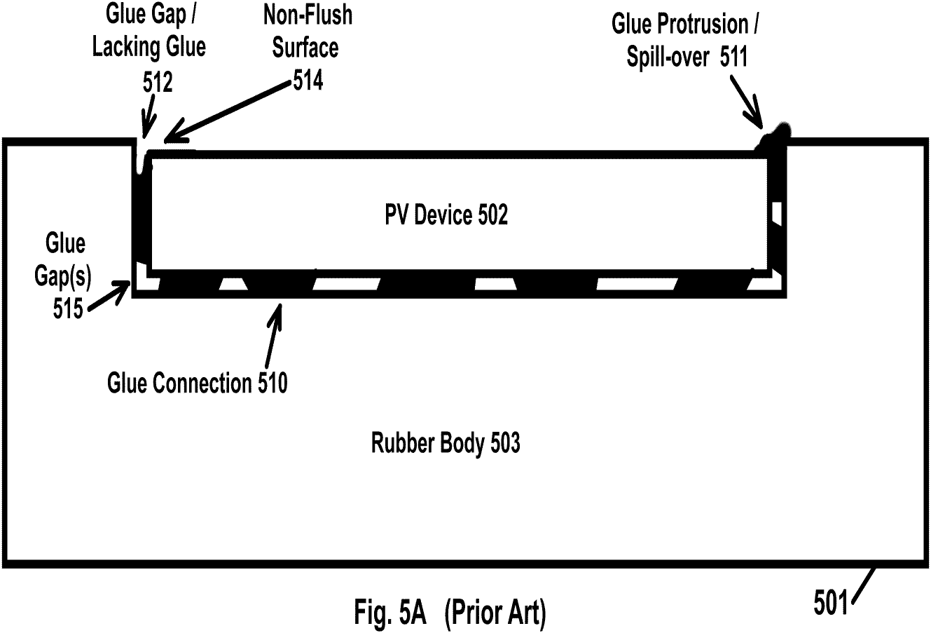

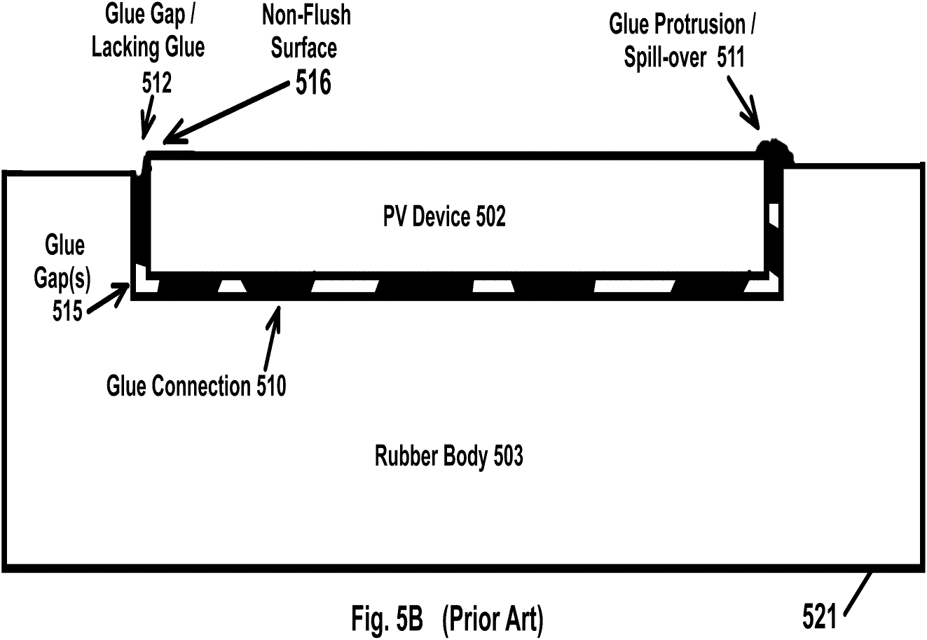

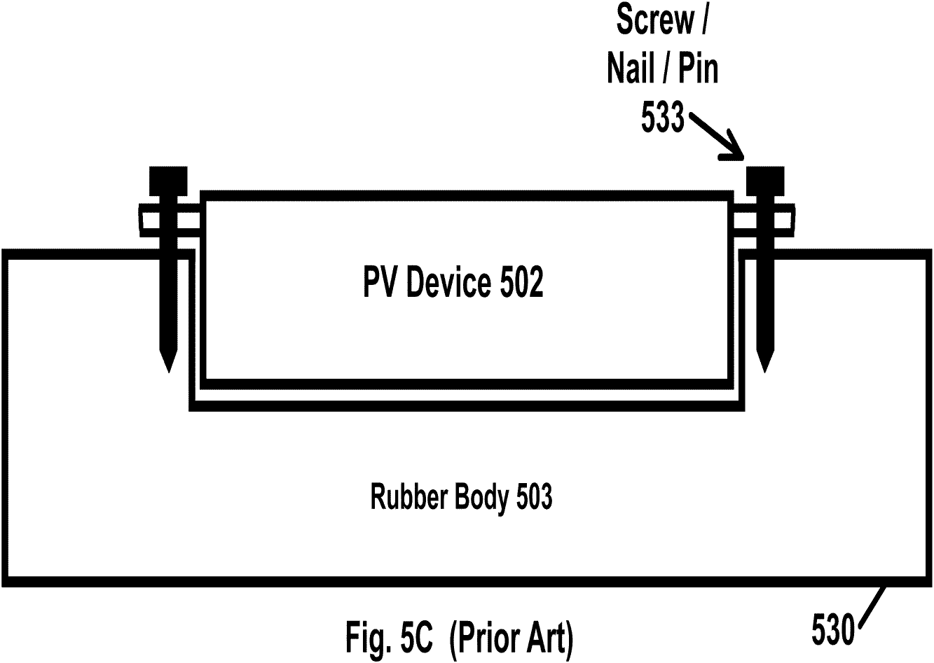

Reference is made to FIG. 5A, which is an illustration of a prior art hybrid non-monolithic product 501; formed by gluing together two discrete and separate objects: (i) a PV device 502, and (ii) an already-prepared rubber body 503 or rubber-based body. As shown, glue connection(s) 510 are used, depicted by black regions; but they often leave one or more Gaps 515, depicted by white spaces or white gaps between the glue regions. Accordingly, the glue-based connection is typically partial, and does not hold in place or glue the entirety of the PV device 502 but rather only portions thereof, thereby decreasing the mechanical resilience of the produce, and/or increasing the probability or the risk that the glue will fail or will weaken over time. Additionally or alternatively, such glue-based connection, which may have gaps or imperfections, may not hold the PV device securely and/or fixedly and/or hermetically.

Additionally or alternatively, a glue protrusion or over-spill 511 is shown, as an example of various glue-based imperfections that may be caused by the gluing; and such imperfection may undesirably cover the product body 503 and/or the sunny-side surface of the PV device 502 (thereby reducing its operational efficiency).

Additionally or alternatively, one or more Glue Gaps 512 are also shown, and they may occur not only within the internal side of the PV device 502, but rather they may occur also at a side or a corner thereof, such that there may exist a spatial gap or a spatial crater or an undesired indentation (arrow 512 points to it) at the top side of the product.

Additionally or alternatively, the product has a non-flush surface 514 or a non-uniform surface height, or suffers from an undesired “step”; as the PV device 502 does not exactly fit into the cavity of the pre-produced rubber body or rubber-based body, but rather, the PV device is slightly recessed within such rubber body or rubber-based.

Additionally or alternatively, the PV device may be non-desirably removed from the rubber body; for example, due to mechanical shocks or forces, or due to the product falling or being subject to mechanical impacts; or due to the shaking of the product (e.g., if the product is moving or spinning, or if the user shakes or moves the product, or if the user attempts to remove the PV device from the rubber body, intentionally or unintentionally); or due to the glue weakening over time, or degrading over time due to age and/or heat and/or environmental changes (e.g., wetness, dryness, extreme temperatures).

Additionally or alternatively, small gaps or air-gaps or channels or regions that lack glue, may capture water or liquid or wetness, or sand or dust, or may trap therein non-desired materials; which may further contribute to weakening of the glue connection, and/or to shortening the life of the glue-based connection; or which may cause, directly or indirectly, damage to the PV device (e.g., trapped grains of sand may rub against the PV device’s sides).

Reference is made to FIG. 5B, which is an illustration of a prior art hybrid non-monolithic product 521; formed by gluing together two discrete and separate objects: (i) a PV device 502, and (ii) an already-molded or already-manufactured rubber body 503. As shown, this product suffers from a different type of non-flush surface 516, such that the PV device 502 is vertically higher relative to the nearby top surface of the rubber body; and such the PV device is slightly protruding out of the rubber body in a non-flush structure and with a non-desired upward step surrounding the edges of the PV device.

Reference is made to FIG. 5C, which is an illustration of a prior art hybrid non-monolithic product 531; formed by connecting together via a screw or nail or pin 512 (or similar mechanical connector) two discrete and separate objects: (i) a PV device 502, and (ii) an already-prepared rubber body 503. As shown, this product suffers from a non-flush surface; for example, the PV device slightly protrudes upwardly out of the rubber body (as demonstrated), or conversely the PV device may be slightly recessed into the rubber body, thereby causing the product to have a non-desired non-flush surface.

Additionally or alternatively, the screw / nail / pin connection mechanism may fail due to mechanical shocks or due to aging. Additionally or alternatively, structural gaps are demonstrated (e.g., white gaps between the rubber body and the PV device), causing the PV device to be slightly movable or shaking or non-fixedly attached to the rubber body in a non-desired or imperfect manner.

Additionally or alternatively, the PV device may be non-desirably removed from the rubber body; for example, due to mechanical shocks or forces, or due to the product falling or being subject to mechanical impacts; or due to a breakage of the screw or nail or pin which may break due to mechanical forces; or due to breakage of a “tooth” or a nut or a protrusion or other element through which the screw or nail or pin is inserted; or due to intentional or non-intentional removal of the screw or pin or nail by a user.

Additionally or alternatively, small gaps or air-gaps or air channels, may capture water or liquids or wetness, or sand or dust, or may trap therein non-desired materials; which may further contribute to weakening of the connection, and/or to shortening the life of the connection; or which may cause, directly or indirectly, damage to the PV device (e.g., trapped grains of sand may rub against the PV device’s sides).

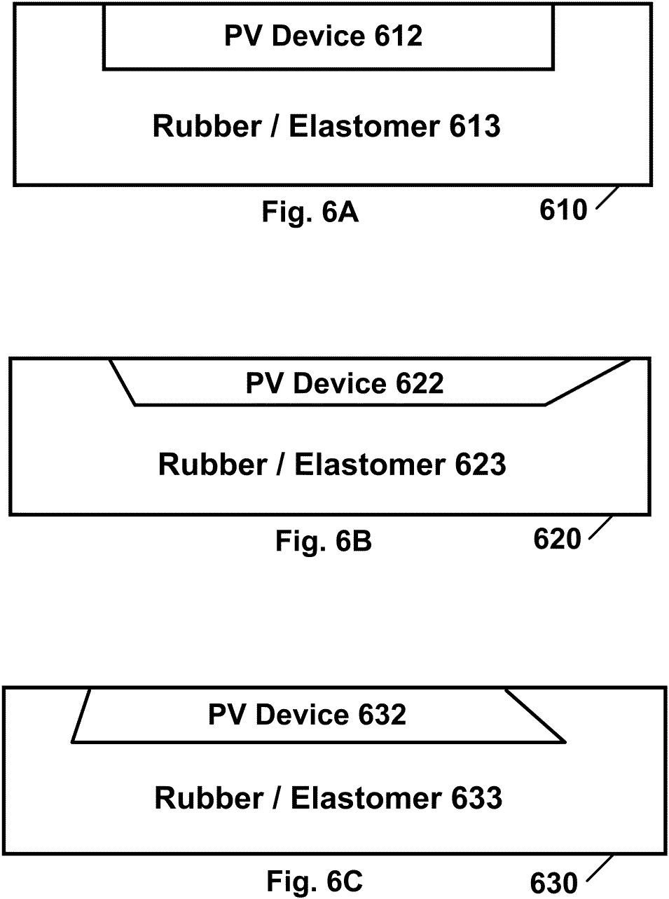

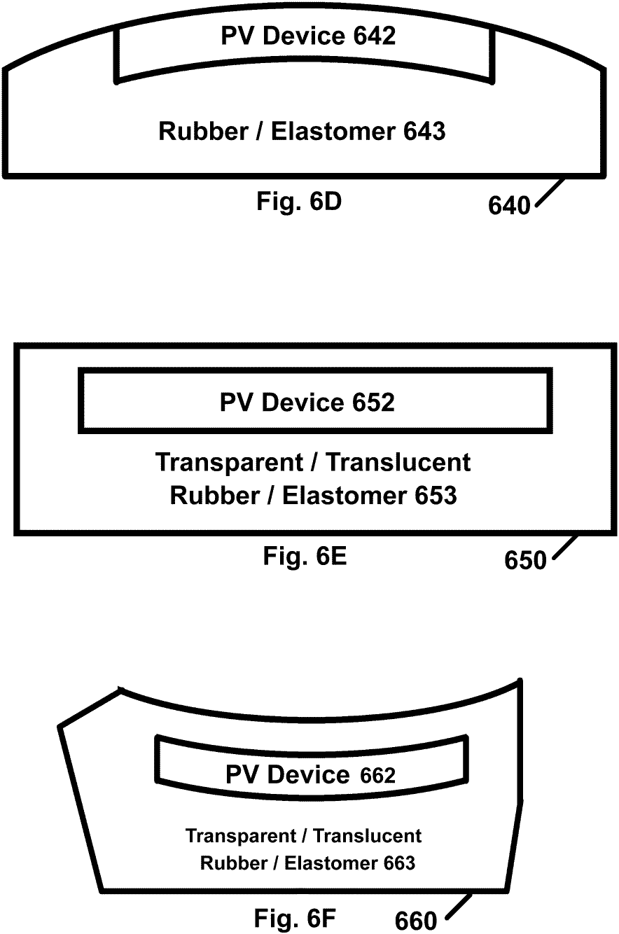

Reference is made to FIG. 6A, which is a schematic illustration of a monolithic rubber-based molded article 610, in accordance with some embodiments. The monolithic article 610 includes an operable PV device 612 that is integrally embedded in or incorporated in a solidified previously-molten or previously-heated rubber / elastomer 613; and that is fixedly and non-removably and non-detachably held in place via a molded connection, namely, via the same molding of rubber / elastomer that created the non-PV-device portion of the monolithic article 610. In some embodiments, the molded article 610 lacks any gaps or glue gaps, or glue protrusions or glue craters, or side-gaps or bottom-side gaps. In some embodiments, the top surface of the molded article 610 is flush and perfect, and there is no under-step or over-step or recess or protrusion; and the PV device is neither recessed nor protruding relative to the nearby top-surface of the rubber regions of the article 610.

Reference is made to FIG. 6B, which is a schematic illustration of another monolithic rubber-based molded article 620, in accordance with some embodiments. The monolithic article 620 includes an operable PV device 622 that is integrally embedded in or incorporated in a solidified previously-molten or previously-heated rubber / elastomer 623. This article 620 may be generally similar to article 610 discussed above; yet one or more side-walls or side-panels or sides or side-borders or side-edges of the PV device 622 may be inwardly-slanted or inwardly-tapered, to achieve a particular structural or functional goal, and/or to improve or enhance or strengthen the molded connection of the PV device and the solidified rubber / elastomer that is adjacent to it (e.g., by increasing the surface area of the PV device that is directly in touch with rubber / elastomer materials).

Reference is made to FIG. 6C, which is a schematic illustration of another monolithic molded article 630, in accordance with some embodiments. The monolithic article 630 includes an operable PV device 632 that is integrally embedded in or incorporated in a solidified previously-molten or previously-heated rubber / elastomer 633. This article 630 may be generally similar to article 610 discussed above; yet one or more side-walls or side-panels or sides of the PV device 632 may be outwardly-slanted or outwardly-tapered, to achieve a particular structural or functional goal, and/or to improve or enhance or strengthen the molded connection of the PV device and the solidified rubber / elastomer that is adjacent to it (e.g., by increasing the surface area of the PV device that is directly in touch with rubber / elastomeric materials), and/or to provide a wedge-shape PV device that has increased or improved integral attachment to its surrounding.

Reference is made to FIG. 6D, which is a schematic illustration of another monolithic molded article 640, in accordance with some embodiments. The monolithic article 640 includes a curved or non-planar or non-flat operable PV device 642 that is integrally embedded in or incorporated in a solidified previously-molten or previously-heated rubber / elastomer 643. The solidified previously-molten or previously-heated rubber / elastomer 643, which typically (but not necessarily) forms the majority of the article, also integrally and/or fixedly and/or securely and/or hermetically holds in place the PV device, without leaving any gaps or holes or protrusions. The PV device, or its top surface or “sunny side” surface, may be curved or concave or convex, or non-planar or non-flat, or may have other three-dimensional structure. The rubber regions of the monolithic article 640 may have a particular three-dimensional shape or structure to achieve particular functional goals. In some embodiments the top surface of the PV device, is precisely flush with the top surface of the rubber body; such that the entirety of the top surface of the article - even though it may be curved or convex or concave or non-planar - is precisely smooth, and lacks any recesses or protrusions or steps.

Reference is made to FIG. 6E, which is a schematic illustration of another monolithic molded article 650, in accordance with some embodiments. The monolithic article 650 includes an operable PV device 652 that is integrally embedded in or incorporated in or “buried in” or “trapped in” or encapsulated within a Transparent or Translucent or Clear or Semi-Clear solidified previously-molten or previously-heated rubber / elastomer 653. The solidified previously-molten or previously-heated rubber / elastomer 653, which typically (but not necessarily) forms the majority of the article, also integrally and/or fixedly and/or securely and/or hermetically holds in place the PV device. In this example, the top surface of the entire article is planar or generally planar; although other types of structures may be used.

Reference is made to FIG. 6F, which is a schematic illustration of another monolithic molded article 660, in accordance with some embodiments. The monolithic article 660 includes a curved or concave or convex or non-flat or nonplanar operable PV device 662 that is integrally embedded in or incorporated in or “buried in” or “trapped in” or encapsulated within a Transparent or Translucent or Clear or Semi-Clear solidified previously-molten or previously-heated rubber / elastomer 663. The solidified previously-molten or previously-heated rubber / elastomer 663, which typically (but not necessarily) forms the majority of the article, also integrally and/or fixedly and/or securely and/or hermetically holds in place the PV device.

Some embodiments may be implemented by using a machine or an automated or semiautomatic production line, which may comprise, for example: a molding unit, an injection molding unit, a compression molding unit, a transfer molding unit, a transfer-compression molding unit, a trimming unit, a cutting unit, a deflashing unit, a heating unit, a storage unit, a cooling unit, an ejection unit; a placement unit or a mounting unit (e.g., to place the PV device at the exact location on the inner-side of the mold cavity or of the female member of the mold); a vacuum unit or suction unit; and/or other suitable units. The components and units of the system may be controlled by a controller or logic circuit, and optionally by a computer which may include, for example, a processor, a memory unit, a storage unit, input units (e.g., keyboard, keypad, touch-screen, touch-pad, mouse, audio microphone), output units (e.g., screen, touch-screen, audio speakers), wired and/or wireless transceivers (e.g., Wi-Fi transceiver, cellular transceiver, Bluetooth transceiver), a power source (e.g., mains electricity, battery, power cell), an Operating System (OS), drivers, applications, and/or other hardware components and/or software components.

In some embodiments, the PV elements are manually or mechanically placed in the mold, and are held in place by gravity, vacuum, adhesive, mechanical anchoring, or some other method before introducing the rubber aggregates to the mold.

In some embodiments, the rubber aggregates may entirely consist (100 percent of it being) recycled rubber or scrap rubber, or residue of previously-used rubber products (e.g., tires); or may include at least 95 or at least 90 percent (e.g., by weight or by volume) of such recycled rubber or scrap rubber, or residue of previously-used rubber products (e.g., tires); thereby providing an ability to manufacture an environmentally-friendly or “green” final article that includes the rubber body and the integrated PV device.

In other embodiments, the rubber aggregates may contain recycled rubber together with non-used or fresh or “virgin” rubber. In yet other embodiments, in addition to rubber aggregates and a binder, other elastomeric and/or polymeric materials may be added to the molding process or to the article production process. For example, foaming agents may be used to reduce the density of the finished article, to reduce stresses in the molded article, to increase buoyancy or floating ability of the finished article, or for other goals.

In some embodiments, the product or the article is structured as, or comprises, a stack of multiple layers; for example:
(I) one or more transparent or translucent protective polymeric layer; for example, polyvinylidene fluoride (PVDF), Ethylene tetrafluoroethylene (ETFE), ethylene chlorotrifluoroethylene (ECTFE), polyethylene terephthalate (PET or PETE) or polyester, Polytetrafluoroethylene (PTFE) or synthetic fluoropolymer of tetrafluoroethylene, epoxy, or other UV-stable transparent or translucent material;
(II) one or more encapsulant layer(s) or encapsulation material layer(s); for example, Thermoplastic polyolefin (TPO), Thermoplastic polyurethane (TPU), ethylene propylene diene monomer (EPDM) or EPDM rubber, Silicone or poly-siloxane (e.g., polymerized siloxanes, or substances whose molecules consist of chains made of alternating silicon and oxygen atoms), Polyolefin Elastomer (POE), Ethylene-vinyl acetate (EVA), poly (ethylene-vinyl acetate) (PEVA), or other UV-stable transparent or translucent material;
(III) an array or matrix or string(s) of solar cells, electrically connected to each other (e.g., in series and/or in parallel);
(IV) an encapsulant material or an encapsulation layer; for example, Polyolefin elastomer (POE), Ethylene-vinyl acetate (EVA), poly (ethylene-vinyl acetate) (PEVA), Thermoplastic polyurethane (TPU), Thermoplastic polyolefin (TPO), ethylene propylene diene monomer (EPDM) or EPDM rubber, Silicone or poly-siloxane (e.g., polymerized siloxanes, or substances whose molecules consist of chains made of alternating silicon and oxygen atoms), or other UV-stable transparent or translucent material;
(V) one or more protective polymeric layer(s); for example, polyvinylidene fluoride (PVDF), Ethylene tetrafluoroethylene (ETFE), ethylene chlorotrifluoroethylene (ECTFE), polyethylene terephthalate (PET or PETE) or polyester, Polytetrafluoroethylene (PTFE) or synthetic fluoropolymer of tetrafluoroethylene, epoxy, or other UV-stable transparent or translucent material;
(VI) a structural layer or a support layer or a structural support layer; for example, containing a high percentage of rubber, or containing (or formed of) at least 75 or at least 80 or at least 85 or at least 90 or at least 95 or at least 97 or at least 99 percent rubber, or consisting of 100 percent rubber.

In some other embodiments, the product or the article is structured as, or comprises, a stack of multiple layers; for example:
(i) one or more transparent or translucent protective polymeric layer; for example, polyvinylidene fluoride (PVDF), Ethylene tetrafluoroethylene (ETFE), ethylene chlorotrifluoroethylene (ECTFE), polyethylene terephthalate (PET or PETE) or polyester, Polytetrafluoroethylene (PTFE) or synthetic fluoropolymer of tetrafluoroethylene, epoxy, or other UV-stable transparent or translucent material;
(ii) one or more encapsulant layer(s) or encapsulation material layer(s); for example, Thermoplastic polyolefin (TPO), Thermoplastic polyurethane (TPU), ethylene propylene diene monomer (EPDM) or EPDM rubber, Silicone or poly-siloxane (e.g., polymerized siloxanes, or substances whose molecules consist of chains made of alternating silicon and oxygen atoms), Polyolefin Elastomer (POE), Ethylene-vinyl acetate (EVA), poly (ethylene-vinyl acetate) (PEVA), or other UV-stable transparent or translucent material;
(iii) an array or matrix or string(s) of solar cells, electrically connected to each other (e.g., in series and/or in parallel);
(iv) an encapsulant material or an encapsulation layer; for example, Polyolefin elastomer (POE), Ethylene-vinyl acetate (EVA), poly (ethylene-vinyl acetate) (PEVA), Thermoplastic polyurethane (TPU), Thermoplastic polyolefin (TPO), ethylene propylene diene monomer (EPDM) or EPDM rubber, Silicone or poly-siloxane (e.g., polymerized siloxanes, or substances whose molecules consist of chains made of alternating silicon and oxygen atoms), or other UV-stable transparent or translucent material;
(v) a structural layer or a support layer or a structural support layer; for example, containing a high percentage of rubber, or containing (or formed of) at least 75 or at least 80 or at least 85 or at least 90 or at least 95 or at least 97 or at least 99 percent rubber, or consisting of 100 percent rubber.

In some embodiments, optionally, the PV device is pre-encapsulated between or within one or more layers of polymeric films or coatings; for example, Ethylene Tetrafluoroethylene (ETFE) film(s) or coating(s) or layer(s); fluorine-based plastic film(s) or coating(s) or layer(s); fluoropolymer film(s) or coating(s) or layer(s); Polyvinylidene Fluoride (PVDF) film(s) or coating(s) or layer(s); thermoplastic fluoropolymer film(s) or coating(s) or layer(s); Thermoplastic Olefin (TPO) film(s) or coating(s) or layer(s); Polyethylene (POE) film(s) or coating(s) or layer(s); Ethylene Vinyl Acetate (EVA) film(s) or coating(s) or layer(s); or a combination of two or more of the above.

In some embodiments, the transparent or translucent protective polymeric layer may be replaced by, or supplemented by, an additional protective layer or layers. Such additional protective layer(s) may be, for example, one or more of the following: (I) a transparent or semi-transparent or translucent or semi-translucent thermosetting polymer (e.g., epoxy, polyester, polyurethane, or other UV-stable transparent or translucent material); (II) a transparent or semi-transparent or translucent or semi-translucent composite material containing a thermosetting polymer (e.g., epoxy, polyester, polyurethane) and further comprising a reinforcing agent or a filling agent (e.g., glass fragments, glass fibers, quartz particles, glass netting); (III) a transparent or semi-transparent or translucent or semi-translucent coating, which may be applied by spraying or brushing or other method.

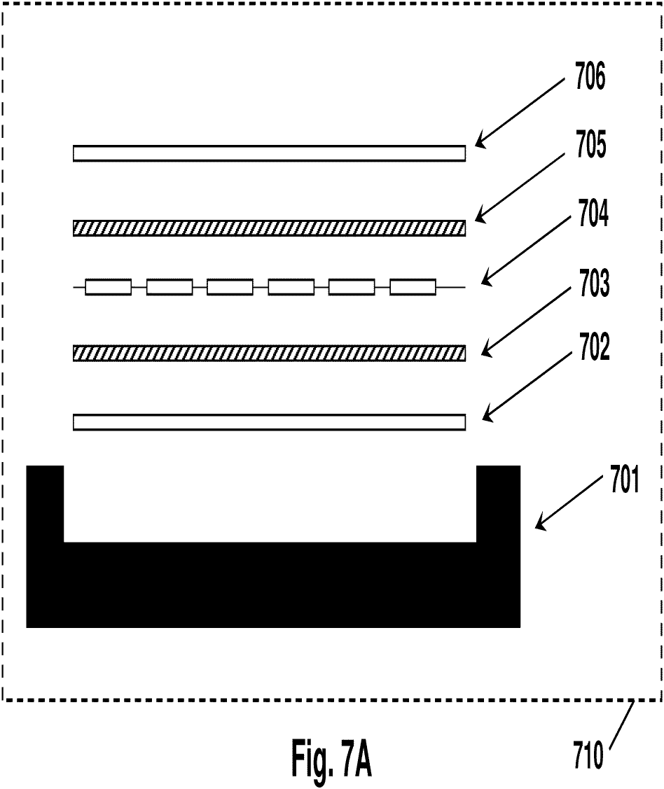

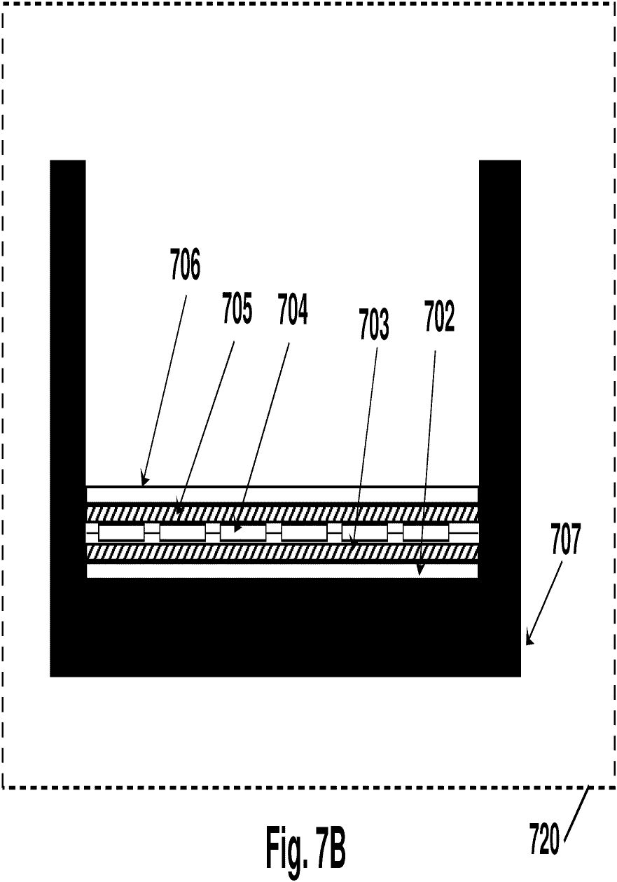

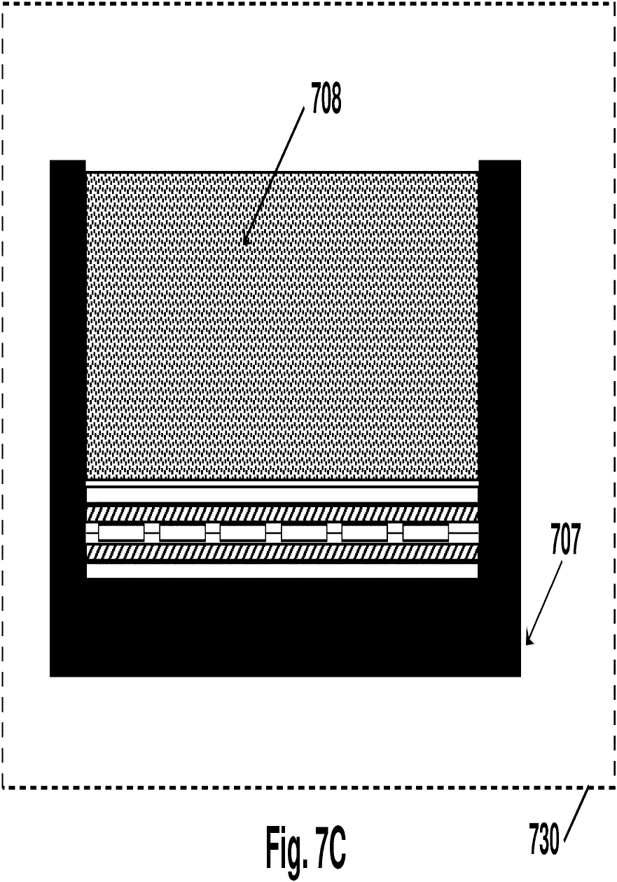

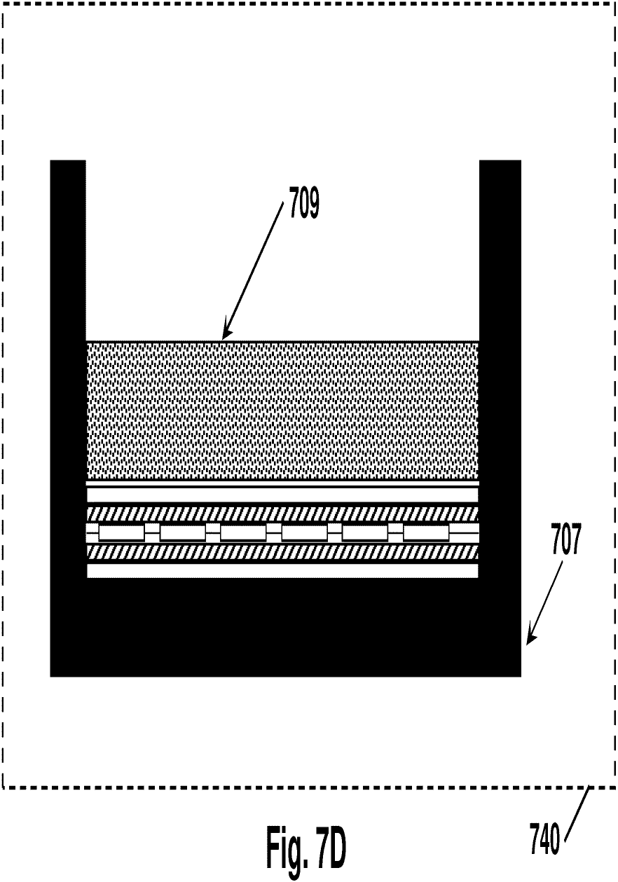

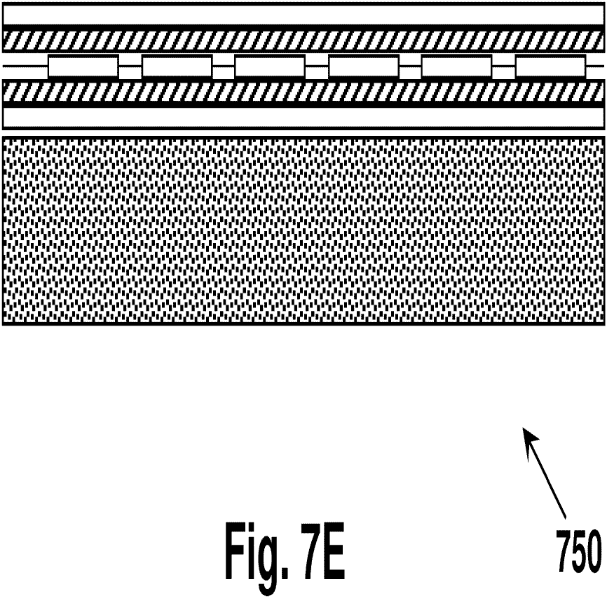

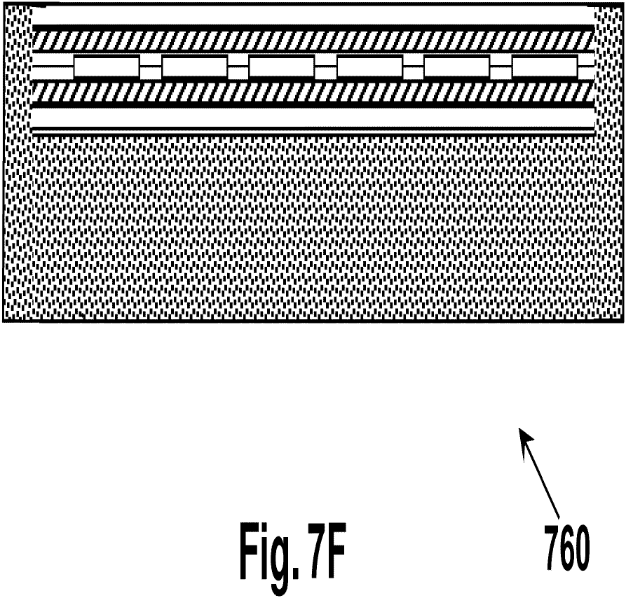

Reference is made to FIGS. 7A to 7D, which demonstrate four steps in a production process of a rubber-based article having a PV device that is integrally integrated with (or incorporated in) a rubber-based body, in accordance with some embodiments.

FIG. 7A shows a set 710 of layers and components; for clarity, they are shown spread apart from each other, although in reality they are placed one on top of the other such that they touch each other.

Arrow 701 indicates a bottom mold of a rubber molding machine, or a bottom member of the mold of a rubber molding machine, or a part or region of the bottom member of the mold of a rubber molding machine.

Arrow 702 indicates a front-sheet or a front-side sheet or a top-sheet or a top-side sheet; for example, formed of a transparent or translucent, UV-stable or UV-resistant, film or encapsulation film or protection film; for example, Ethylene tetrafluoroethylene (ETFE) film or sheet or coating, a fluoro-polymer film or sheet or coating, Polyvinylidene Fluoride (PVDF) film, or Polyvinylidene Fluoride Resin film; a film or protection layer that has weatherability properties and/or that is weather-resistant, resistant to a wide range of temperatures; having corrosion resistance or corrosion resilience; having mechanical resilience; having electrical insulating properties (e.g., non electrically conducting); having a low friction coefficient; having a high tensile strength having abrasion resistance properties; having high chemical resistance; having low water absorption properties. In some embodiments, the top-side or front-side protective sheet is non-rigid and/or non-brittle; or is rigid-flex or is rigid-and-flexible; such that it does not break and/or does not crack in response to mechanical forces of, for example, a human stepping on the finished article, or a bicycle or motorcycle driving on it, or (in some implementations) a vehicle driving on it. In some embodiments, optionally, this layer (arrow 702) may be replaced by, or implemented as, a layer of wet or dry layup, or as a prepreg layer, or a layer of glass fiber cloth or weave that is impregnated or interwoven with a resin or a resin bonding agent, or as an insulation layer, or as a layer of dielectric material, or a layer or of thermoset-based composite materials (e.g., epoxy, polyester, polyurethane); and such layer may be transparent or translucent, or at least partially transparent or at least partially translucent, or at least 90% transparent, or at least 90% translucent, as this layer protects or encapsulates or covers or coats the sunny-side of the PV device / solar cell array.

Arrow 703 indicates a front-side encapsulant, or a front-side encapsulation layer, or a top encapsulant, or a top-side encapsulant, or a top-side encapsulation layer; for example, made of ethylene vinyl acetate (EVA) or polyethylene vinyl acetate (PEVA) film or sheet or coating or encapsulation layer; having at least 90 percent transparency to light or to visible light; which may provide to the solar cell / PV device water resistance properties, mechanical forces dissipation and absorption, mechanical protection to components of the solar cell / PV device and to electrodes or wires, mechanical vibrations protection or absorption, blocking of ingress water, barrier against liquids or vapors or moisture, and/or having other properties. In some embodiments, the top-side or front-side encapsulant is non-rigid and/or non-brittle; or is rigid-flex or is rigid-and-flexible; such that it does not break and/or does not crack in response to mechanical forces of, for example, a human stepping on the finished article, or a bicycle or motorcycle driving on it, or (in some implementations) a vehicle driving on it. In some embodiments, optionally, this layer (arrow 703) may be replaced by, or implemented as, a layer of wet or dry layup, or as a prepreg layer, or a layer of glass fiber cloth or weave that is impregnated or interwoven with a resin or a resin bonding agent, or as an insulation layer, or as a layer of dielectric material, or a layer or of thermoset-based composite materials (e.g., epoxy, polyester, polyurethane); and such layer may be transparent or translucent, or at least partially transparent or at least partially translucent, or at least 90% transparent, or at least 90% translucent, as this layer protects or encapsulates or covers or coats the sunny-side of the PV device / solar cell array.

Arrow 704 indicates a solar cell array, or an array (or matrix, or arrangements, or one or more strings) of solar cell, that are inter-connected to each other in series and/or in parallel; for example, made from (or using) silicon crystalline wafer(s), silicon poly-crystalline wafer(s), silicon mono-crystalline wafer(s), having mono-crystalline silicon cells, having cast mono-crystalline cells, having poly-crystalline silicon cells, and/or other types of cells.

Arrow 705 indicates a back-side encapsulant, or a back-side encapsulation layer, or a bottom or bottom-side encapsulant, or a bottom or bottom-side encapsulation layer; for example, made of ethylene vinyl acetate (EVA) or polyethylene vinyl acetate (PEVA) film or sheet or coating or encapsulation layer, or made of polypropylene (PP) or polyethylene terephthalate (PET) or Polyvinyl fluoride (PVF). In some embodiments, the back-side or bottom-side encapsulant is not, or need not be, transparent or translucent. The back-side or bottom-side encapsulant may provide mechanical protection, electrical insulation, and/or thermal stability; and may assist in mechanical shock absorption, water protection, moisture protection, barrier against liquids or vapors or moisture, or other encapsulation goals. In some embodiments, the bottom-side protective sheet is non-rigid and/or non-brittle; or is rigid-flex or is rigid-and-flexible; such that it does not break and/or does not crack in response to mechanical forces of, for example, a human stepping on the finished article, or a bicycle or motorcycle driving on it, or (in some implementations) a vehicle driving on it. In some embodiments, optionally, this layer (arrow 705) may be replaced by, or implemented as, a layer of wet or dry layup, or as a prepreg layer, or a layer of glass fiber cloth or weave that is impregnated or interwoven with a resin or a resin bonding agent, or as an insulation layer, or as a layer of dielectric material, or a layer or of thermoset-based composite materials (e.g., epoxy, polyester, polyurethane); and such layer may optionally be transparent or translucent, or at least partially transparent or at least partially translucent, or it may be non-transparent or non-translucent or light-blocking or opaque or colored, since this layer protects or encapsulates or covers or coats the “dark side” (and not the sunny-side) of the PV device / solar cell array.

Arrow 706 indicates a back-sheet or a back-side sheet, or a bottom-sheet or bottom-side sheet; for example, formed of film or sheet or coating; optionally being transparent or translucent; typically being UV-stable or UV-resistant; for example, Ethylene tetrafluoroethylene (ETFE) film or sheet or coating, a fluoro-polymer film or sheet or coating, Polyvinylidene Fluoride (PVDF) film, or Polyvinylidene Fluoride Resin film; a film or protection layer that has weatherability properties and/or that is weather-resistant, resistant to a wide range of temperatures; having corrosion resistance or corrosion resilience; having mechanical resilience; having electrical insulating properties (e.g., non electrically conducting); having a low friction coefficient; having a high tensile strength having abrasion resistance properties; having high chemical resistance; having low water absorption properties. In some embodiments, the bottom-side encapsulant is non-rigid and/or non-brittle; or is rigid-flex or is rigid-and-flexible; such that it does not break and/or does not crack in response to mechanical forces of, for example, a human stepping on the finished article, or a bicycle or motorcycle driving on it, or (in some implementations) a vehicle driving on it. In some embodiments, optionally, this layer (arrow 706) may be replaced by, or implemented as, a layer of wet or dry layup, or as a prepreg layer, or a layer of glass fiber cloth or weave that is impregnated or interwoven with a resin or a resin bonding agent, or as an insulation layer, or as a layer of dielectric material, or a layer or of thermoset-based composite materials (e.g., epoxy, polyester, polyurethane); and such layer may optionally be transparent or translucent, or at least partially transparent or at least partially translucent, or it may be non-transparent or non-translucent or light-blocking or opaque or colored, since this layer protects or encapsulates or covers or coats the “dark side” (and not the sunny-side) of the PV device / solar cell array.

FIG. 7B shows a set 720 of layers and components: the items shown in FIG. 7A has been placed into the bottom member (or bottom part) of the mold of the rubber molding machine, one layer (or one component) on top of the other.

FIG. 7C shows a set 730 of layers and components: the items shown in FIG. 7B remain as they are, and rubber 708 has been placed or added or inserted above those components, such that the rubber 708 fills (partially or entirely) the cavity that is located above the bottom member of the mold. Rubber 708 may be or may include, for example, raw rubber materials, recycled rubber, pre-used rubber, pre-used rubber products, scrap rubber, rubber granules or pellets or particles or strips or lumps or chunks, a mixture of recycled rubber and “virgin” non-recycled rubber, a mixture having at least 90 or 95 or 99 percent of recycled rubber or scrap rubber, or other rubber-containing mixture.

FIG. 7D shows a set 740 of layers and components: the items shown in FIG. 7C remain in their arranged order, but rubber 708 was subject to compression and/or compacting, particularly by being heated and compressed and compacted (e.g., by forces of plunger or a screw or a compression plate). The original rubber 708 (e.g., rubber granules or pellets) has been modified, via heat and compression and compacting, into a compacted rubber body 709; which directly touches the back-side sheet 706.

The final rubber-based article is shown in FIG. 7D, still within the bottom-member of the mold. The article is then ejected or extracted or removed from the mold; and it is typically turned upside down (or, rotated by 180 degrees), such that the compacted rubber body 709 would be facing the ground, and the PV device and its surrounding layers would be facing upwardly (e.g., towards the sun or the sky).

Reference is made to FIG. 7E, which is a schematic illustration of an integrated molded article 750 in accordance with some demonstrative embodiments. Article 750 is the article that was produced in the steps shown in FIGS. 7A to 7D, and that was shown still within the mold in FIG. 7D. The article 750 is shown in FIG. 7E after it was extracted or ejected or removed from the mold, and after it was turned upside down (or rotated by 180 degrees).

Reference is made to FIG. 7F, which is a schematic illustration of another integrated molded article 760 in accordance with some demonstrative embodiments. Article 760 is generally similar to article 750 described above; however, in article 760, the compacted or molded rubber body is located not only beneath the PV device of the final integrated article, but also on the sides (e.g., right and left) of the PV device, thereby providing a rubber-based body frame that frames the PV device from five out of six directions (from beneath the PV device; and from the four horizontal directions that are at the same horizontal plane as the PV device), leaving a single direction (upward direction) that is not covered by rubber. Other suitable structures may be achieved in accordance with various embodiments.

In a demonstrative embodiment, the PV device that is created this way, may be part of a pavement tile or a road or a trail or a walking path, or a flooring tile or carpeting tile, or a playground tile or a sports-ground tile; such that a person may step on the PV device, which is flexible and absorbs mechanical shocks without being operably damaged; and the rubber body of the article, which is beneath the PV device, absorbs and dissipates mechanical shocks and mechanical forces, and optionally also provides an elastic feedback or elastic response to the forces applied to it (e.g., the person feels that he is walking or stepping on a partially-flexible pavement or flooring element, rather than on an entirely rigid floor).

In some embodiments, the article having a PV device that is integrally integrated in a rubber body, may be a paving element (e.g., intended for pedestrian use in sidewalks), a sidewalk tile, a driveway tile, a pavement tile, a road tile, a trail tile, a sidewalk portion, a driveway portion, a pavement tile, a flooring item, a floor tile, or other article that is intended for humans to walk upon or step upon.

In some embodiments, the article having a PV device that is integrally integrated in a rubber body, may be a paving element for use in roads, vehicular roads, cycling paths, bicycling paths, and/or parking lots.

In some embodiments, the article having a PV device that is integrally integrated in a rubber body, may be a paving element or a flooring element or a carpeting element intended for use in recreational areas, sports-grounds, parks, playgrounds, schools, kindergartens, play yards, play areas for toddlers or children, or floors of a fitness center or a gym or a recreational center.

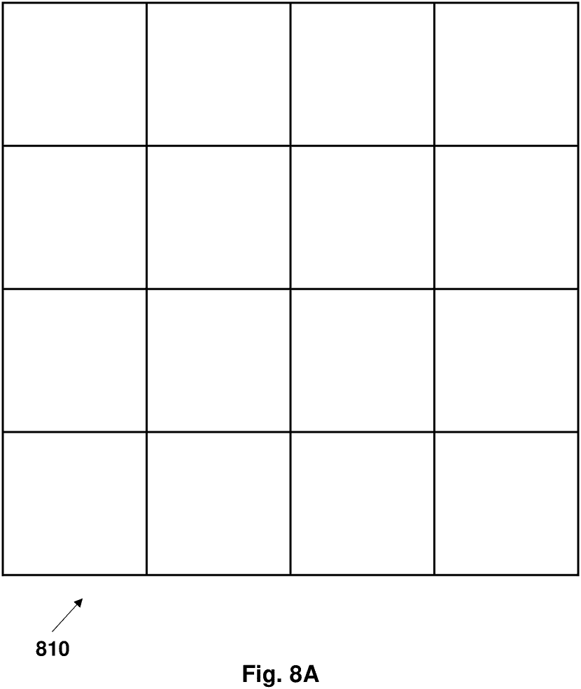

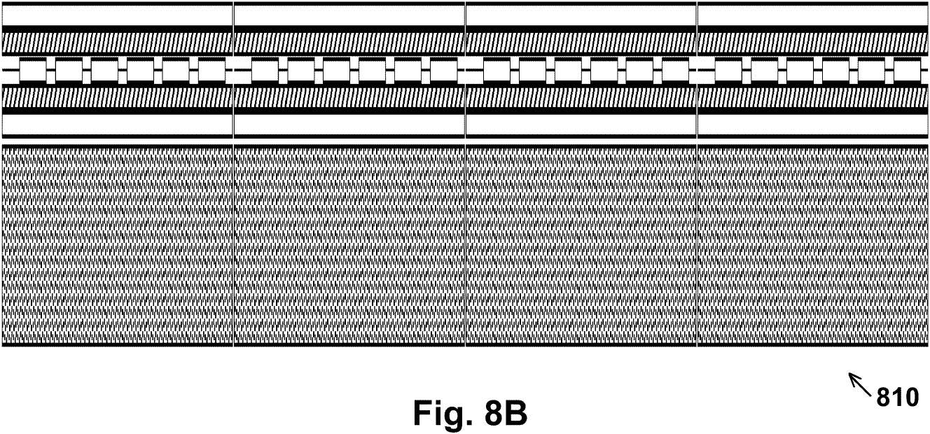

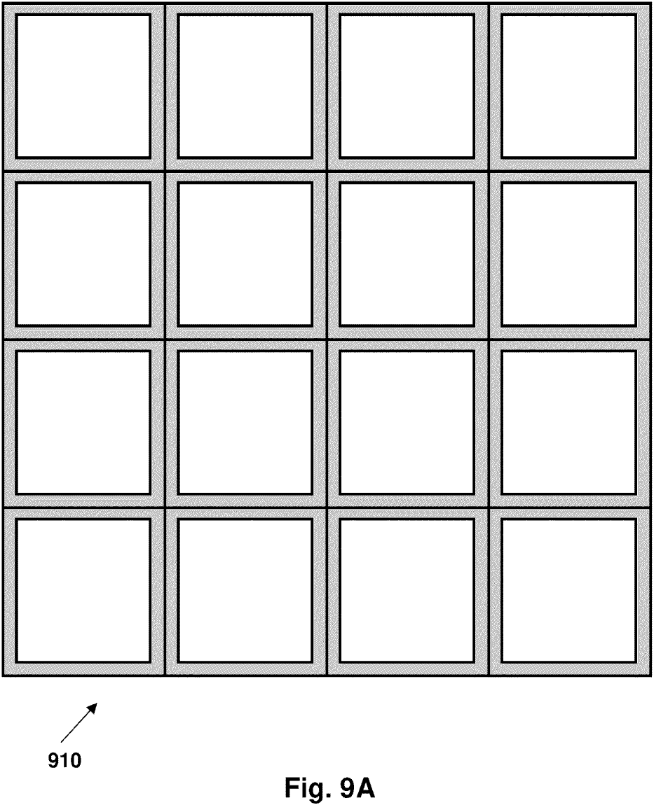

Reference is made to FIG. 8A, which is a schematic illustration of a top-side view of a set 810 of pavement tiles, in accordance with some demonstrative embodiments; and also to FIG. 8B, which is a schematic illustration of a side-side view of that set 810 of pavement tiles, in accordance with some demonstrative embodiments.

For example, set 810 includes a matrix or an array of pavement tiles. As non-limiting examples, each tile of set 810 may be rectangular or square-shaped; although other structures may be implemented and used, such as, triangular tiles; circular tiles; semi-circular pavement tiles; pentagon shaped tiles; polygon shaped tiles; or even a free-shape tile (e.g., a snake-shaped tile or a serpentine tile, a zig-zag shaped tile, or the like). For demonstrative purposes, the tiles are shown as arranged in an array having rows and columns; however, other suitable arrangements or structures may be used, and they need not necessarily be symmetrical.

Innovatively, the top-side or the top-surface or the top-region of each of these tiles of set 810 is an active and operable PV device, on which humans can step or walk or run or play (e.g., in a children’s playground), and/or on which humans may ride a bicycle or a scooter or an electric scooter or even (in some embodiments) a vehicle; and each such active and operable PV device generates electricity from light or sunlight when its top surface (or at least a portion of its top surface) is not temporarily covered by a human who steps on it, or by a human or an object that temporarily obstructs light or sunlight.

The active and operable PV device of each tile of set 810, does not break and/or does not crack and/or does not become damaged, and remains operable or at least partially operable (e.g., to a sufficient degree of utility or efficiency), even though it is exposed to mechanical shocks and/or mechanical pressures; due to, particularly, (I) the inclusion of a PV device or solar cell that is pre-manufactured to be flexible and/or rollable and/or foldable and/or breakable (e.g., due to introduction of non-transcending gaps or “blind gaps” into a wafer or substrate of the PV device, and/or sue to introduction of a filler material into those non-transcending gaps or “blind gaps”), and/or (II) the integrated connection or molded connection between the active and operable PV device and the rubber body that is integrally connected beneath it and contributes to absorption and/or dissipation of such mechanical shocks and/or mechanical forces.

For demonstrative purposes, the pavement tiles of set 810 are directly touching each other, in the horizontal plane, such that there are no gaps or air-gaps between a pair of two adjacent tiles. In other embodiments, the pavement tiles of set 810 may have gaps between them or among them; and such gaps may be filled with one or more filler materials, for example, sand, epoxy, resin, pellets, plastic pellets, rubber pellets, or other suitable materials.

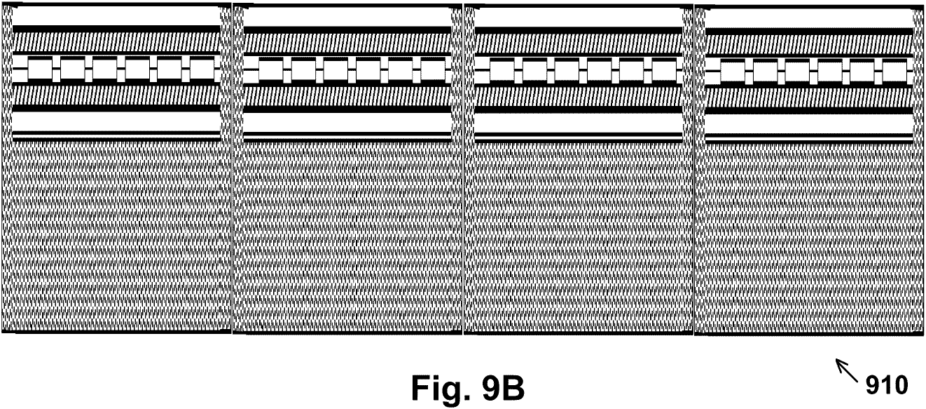

Reference is made to FIG. 9A, which is a schematic illustration of a top-side view of a set 910 of pavement tiles, in accordance with some demonstrative embodiments; and also to FIG. 9B, which is a schematic illustration of a side-side view of that set 910 of pavement tiles, in accordance with some demonstrative embodiments.

For example, set 910 includes a matrix or an array of pavement tiles. Each tile comprises a central region, which is the active and operable PV device; that is surrounded (in the horizontal plane) by a border or frame that is formed or rubber; such that the rubber border or rubber frame holds in place the central active and operable PV device of each tile. The rubber border or rubber frame of a particular tile, and the central active and operable PV device of that tile, are mechanically and integrally inter-connected to each other by means of the molded rubber or the solidified rubber or the rubber-based connection that was integrally formed, around and adjacent to the central active and operable PV device of each tile, during (or concurrently with) the manufacturing of the rubber frame or rubber body of each tile. Additionally, there is a rubber body or rubber layer which is beneath each active and operable PV device; and which is also mechanically and integrally inter-connected to the PV device by means of the molded rubber or the solidified rubber or the rubber-based connection that was integrally formed during (or concurrently with) the manufacturing of the rubber body of each tile.

As non-limiting examples, each tile of set 910 may be rectangular or square-shaped; although other structures may be implemented and used, such as, triangular tiles; circular tiles; semi-circular pavement tiles; pentagon shaped tiles; polygon shaped tiles; or even a free-shape tile (e.g., a snake-shaped tile or a serpentine tile, a zig-zag shaped tile, or the like). For demonstrative purposes, the tiles are shown as arranged in an array having rows and columns; however, other suitable arrangements or structures may be used, and they need not necessarily be symmetrical.

Innovatively, the top-side or the top-surface or the top-region of each of these tiles of set 910 is an active and operable PV device, on which humans can step or walk or run or play (e.g., in a children’s playground), and/or on which humans may ride a bicycle or a scooter or an electric scooter or even (in some embodiments) a vehicle; and each such active and operable PV device generates electricity from light or sunlight when its top surface (or at least a portion of its top surface) is not temporarily covered by a human who steps on it, or by a human or an object that temporarily obstructs light or sunlight.

The active and operable PV device of each tile of set 910, does not break and/or does not crack and/or does not become damaged, and remains operable or at least partially operable (e.g., to a sufficient degree of utility or efficiency), even though it is exposed to mechanical shocks and/or mechanical pressures; due to, particularly, (I) the inclusion of a PV device or solar cell that is pre-manufactured to be flexible and/or rollable and/or foldable and/or breakable (e.g., due to introduction of non-transcending gaps or “blind gaps” into a wafer or substrate of the PV device, and/or sue to introduction of a filler material into those non-transcending gaps or “blind gaps”), and/or (II) the integrated connection or molded connection between the active and operable PV device and the rubber body that is integrally connected beneath it and contributes to absorption and/or dissipation of such mechanical shocks and/or mechanical forces, and/or the integrated connection or molded connection between the active and operable PV device (which is at the center of each tile) and the rubber frame or the rubber border that surrounds the PV device and that is integrally connected to the PV device and also contributes to absorption and/or dissipation of such mechanical shocks and/or mechanical forces.

For demonstrative purposes, the pavement tiles of set 910 are directly touching each other, in the horizontal plane, such that there are no gaps or air-gaps between a pair of two adjacent tiles; and such that the rubber border or the rubber frame of a first tile, is directly touching the rubber frame or the rubber body of a second, neighboring, tile. In other embodiments, the pavement tiles of set 910 may have gaps between them or among them; and such gaps may be filled with one or more filler materials, for example, sand, epoxy, resin, pellets, plastic pellets, rubber pellets, or other suitable materials.

For demonstrative purposes, set 810 and/or set 910 are described as pavement tiles or paving tiles; however, they may similarly be implemented as, for example, flooring tiles, carpeting tiles, playground tiles, walking trail tiles, bicycle trail tiles, vehicular trail tiles, recreational activity tiles, fitness center tiles, roofing tiles, roofing elements, tiles of a structure that covers or protects another object (e.g., a vehicle, a boat, a marine vessel, a motorcycle, a container, a storage container), or tiles or elements of other suitable nature. In some embodiments, neighboring tiles may be glued or bonded to each other using glue or bonding material, or may be connected to each other using mechanical connections or pins or hooks or male-female connectors, or using other suitable mechanisms.

In some embodiments, in set 810, the PV device or solar cell array occupies an entirety of the top surface or an entirety of the top area of each tile. In contrast, in set 910, the PV device or solar cell array occupies most, but not all, of the top surface or the top area of each tile, since there is also a rubber border or rubber frame that surrounds the central or generally-central PV device or solar cell array.

In some embodiments, the rubber border or rubber frame of each tile in set 910, occupies less than 25 percent of the total top-surface area of the tile; or occupies less than 20 percent of the total top-surface area of the tile; or occupies less than 15 percent of the total top-surface area of the tile; or occupies less than 10 percent of the total top-surface area of the tile; or occupies less than 5 percent of the total top-surface area of the tile. In some embodiments, the rubber border or rubber frame of each tile in set 910, occupies between 5 to 25 percent of the total top-surface area of the tile.

In some embodiments, the PV device or solar cell array of each tile in set 910, occupies at least 75 percent of the total top-surface area of the tile; or occupies at least 80 percent of the total top-surface area of the tile; or occupies at least 85 percent of the total top-surface area of the tile; or occupies at least 90 percent of the total top-surface area of the tile; or occupies at least 95 percent of the total top-surface area of the tile. In some embodiments, the PV device or solar cell array of each tile in set 910, occupies between 75 to 95 percent of the total top-surface area of each tile; or occupies between 75 to 98 percent of the total top-surface area of each tile.

In some embodiments, the tiles (e.g., pavement tiles, paving tiles, flooring tiles, roof tiles, or the like) of set 810 or of set 910, may comprise the PV device or solar cell array which is shaped or structured as square or generally square top-region or top-surface. The Applicants have realized some embodiments may provide an optimal or improved or enhanced efficiency, for example, if each independent or discrete solar cell, of the PV device or solar cell array of a tile, has a horizontal length dimension L, and has a horizontal width dimension W, such that 12.5 centimeters < L < 25 centimeters, and such that 12.5 centimeters < W < 25 centimeters. The Applicants have realized that in some embodiments, structuring the PV device or solar cell array of a tile, to be composed of an arrangement of side-by-side solar cells, each solar cell being a flexible and/or foldable and/or bendable and/or rollable PV device, each such flexible solar cell having horizontal width and horizontal length that are (each one of them) in the range of 12.5 and 25 centimeters, contributes to enhancing the efficiency and longevity of each particular flexible solar cell and also the entire tile and the entirety of the PV device or solar cell array of such tile; and/or provides an optimal balance between efficiency of electricity production on the one hand, and avoidance or reduction of mechanical cracks or mechanical breakage or mechanical damage on the other hands; and/or provides to each tile, and to each PV device or solar cell array of a tile, the suitable and efficient ability to remain flexible and/or elastic upon application of mechanical forces, yet also to remain generally planar and to avoid forming a deep crater or a deep valley when a person steps on or walks on such tile. This specific range of dimensions is also counterintuitive, as conventional solar panels (e.g., rigid and glass-covered solar panels or non-flexible solar cells) that are typically installed (e.g., on roofs, or in solar energy harvesting fields) have sizes or dimensions that are greater than the above range by an entire order of magnitude, and they often span several meters in length and several squared-meters in area. In some embodiments, the dimensions of an entire tile, which consists of several such side-by-side inter-connected (mechanically and electrically) discrete and flexible solar cells, may have tile dimensions of, for example, 80 × 80 or 90 × 90 or 100 × 100 centimeters. Other suitable dimensions may be used.

In some embodiments, the article having a PV device that is integrally integrated in a rubber body, may be a roofing element, a roof element, a roof tile, a roof shingle, a shingle, a roof cover, a roof element having sealing properties, or other roof structure or roof portion.

In some embodiments, the article having a PV device that is integrally integrated in a rubber body, may be a paving element to allow maintenance or repairs to be performed on a roof.

In some embodiments, the article having a PV device that is integrally integrated in a rubber body, may be a curb edge element intended for use at the edge of a sidewalk or driveway or pavement or road or other trail.

In some embodiments, the article having a PV device that is integrally integrated in a rubber body, may be a bollard, a road sign, a traffic sign, a traffic light, a traffic control box, a traffic light control box, or a vehicular traffic-related object or item.

In some embodiments, the article having a PV device that is integrally integrated in a rubber body, may be a seat, a portion of a seat, a portion of a furniture item, a tile, a flooring element, or a carpeting element.

In some embodiments, the article having a PV device that is integrally integrated in a rubber body, may be a buoy, a floating device, a floating sign, a floating marker, a floating navigation marker, an anchored floating device, a non-anchored floating device, a weather buoy, a sea mark buoy, a light-emitting buoy, a diver’s marking buoy, a rescue or life-saving buoy, a wave-monitoring buoy, a weather-monitoring buoy, a floater, a solar floater article, or a solar panel or PV device that is intended to float on water and to generate electricity while floating on water; and in some embodiments, such article may optionally include foamed rubber or foamed elements, in order to make the total Specific Weight of the article smaller than 1 and thus enabling the article to float on water.

In some embodiments, optionally, the solar cell or PV device may be a mechanically-resilient and/or flexible and/or rollable and/or bendable and/or foldable solar cell or PV device; for example, due to having non-transcending gaps or “blind gaps” or craters that penetrate into from 80 to 99.9 percent of the depth of the semiconductor wafer; which provide mechanical resilience, and/or enhanced ability to absorb and/or dissipate mechanical forces and/or mechanical shocks; including, but not limited to, structures and/or components as described in United States patent number US 11,081,606 B2, which is hereby incorporated by reference in its entirety.

Some embodiments may comprise or may utilize one or more units, components, features, methods and/or systems that are described in patent application US 17/353,867, filed on Jun. 22, 2021, which is hereby incorporated by reference in its entirety.

Some embodiments may comprise or may utilize one or more units, components, features, methods and/or systems that are described in PCT international application number PCT/IL2021/051269, having an international filing date of Oct. 27, 2021, which is hereby incorporated by reference in its entirety.

Some embodiments may comprise or may utilize one or more units, components, features, methods and/or systems that are described in PCT international application number PCT/IL2021/051202, having an international filing date of Oct. 7, 2021, which is hereby incorporated by reference in its entirety.

Some embodiments provide an apparatus comprising: (a) a rubber body, formed of one or more solidified, compacted, previously-heated rubber materials, selected from the group consisting of: virgin unused rubber material, recycled rubber, scrap rubber, rubber pellets, rubber granules, rubber lumps, rubber strips; and (b) an operable photovoltaic (PV) device, that is configured to generate electricity from light via the photovoltaic effect. The operable photovoltaic device is integrally held on top of said rubber body, via a molded connection and holding mechanism which molds together (i) said rubber body and (ii) said operable photovoltaic device.

In some embodiments, the operable photovoltaic device is held in place on said rubber body only via molding together of said operable photovoltaic device with said one or more rubber materials, and not via any screws or any glue or any detachable attachment mechanism.

In some embodiments, the operable photovoltaic device is a flexible and rollable operable photovoltaic device, and comprises a semiconductor substrate having a plurality of non-transcending craters that penetrate into from 80 percent to 99.9 percent of a depth of said semiconductor substrate. The plurality of non-transcending craters in said semiconductor substrate, segment said semiconductor substrate and said operable photovoltaic device into a plurality of sub-regions, and provide to said operable photovoltaic device properties of absorption and dissipation of mechanical forces and/or mechanical shocks and/or mechanical pressure and/or thermal forces, and provide to said operable photovoltaic device an ability to remain operable even after being subjected to high-temperature and high-pressure of a rubber article manufacturing machine.

In some embodiments, the operable photovoltaic device is a flexible and rollable operable photovoltaic device which comprises the following layers: (I) a non-rigid top-side protection sheet, that is at least 75 percent transparent or translucent; (II) a non-rigid top-side encapsulant, that is at least 75 percent transparent or translucent; (III) an array of solar cells, that are inter-connected in series and/or in parallel; (IV) a non-rigid bottom-side encapsulant; (V) a non-rigid bottom-side protection sheet; wherein said operable photovoltaic device is integrally mounted on, and is non-detachably attached to, said rubber body (i) which provides elasticity to said operable photovoltaic device and its layers, and (ii) which absorbs mechanical shocks and forces that are applied onto said operable photovoltaic device and its layers. In some embodiments, the rubber-based article is a tile, or a pavement tile, or a roofing tile, which is composed of an arrangement of side-by-side inter-connected (mechanically and electrically) flexible non-brittle solar cells; each such flexible solar cell being an operable photovoltaic device which a flexible and rollable operable photovoltaic device, and comprises a semiconductor substrate having a plurality of non-transcending craters or gaps or “blind gaps” that penetrate into from 80 percent to 99.9 percent of a depth of said semiconductor substrate or wafer (and do not penetrate all through the entire depth of the semiconductor substrate or wafer); optionally with filler material(s) that fill (entirely or partially) such non-transcending gaps and thus contribute to mechanical resilience of the flexible solar cell and/or contribute to absorption and dissipation of mechanical forces; wherein the plurality of non-transcending craters or gaps or “blind gaps” in said semiconductor substrate, segment said semiconductor substrate and said operable photovoltaic device into a plurality of sub-regions, and provide to said operable photovoltaic device properties of absorption and dissipation of mechanical forces and/or mechanical shocks and/or mechanical pressure and/or thermal forces, and provide to said operable photovoltaic device an ability to remain operable even after being subjected to high-temperature and high-pressure of a rubber article manufacturing machine.

In some embodiments, the operable photovoltaic device is a flexible and rollable operable photovoltaic device which comprises the following layers: (I) a non-rigid top-side protection sheet, that is at least 75 percent transparent or translucent; (II) a non-rigid top-side encapsulant, that is at least 75 percent transparent or translucent; wherein at least one of: the non-rigid top-side protection sheet, and the non-rigid top-side encapsulant, comprises one or more of: (i) a non-rigid glass fiber weave, that is impregnated or interwoven with a resin, (ii) a layer of thermoset-based composite materials that includes at least one of epoxy, polyester, polyurethane; (III) an array of solar cells, that are inter-connected in series and/or in parallel; (IV) a non-rigid bottom-side encapsulant; (V) a non-rigid bottom-side protection sheet. In some embodiments, at least one of: the non-rigid bottom-side protection sheet, and the non-rigid bottom-side encapsulant, comprises one or more of: (i) a non-rigid glass fiber weave, that is impregnated or interwoven with a resin, (ii) a layer of thermoset-based composite materials that includes at least one of epoxy, polyester, polyurethane. In some embodiments, said operable photovoltaic device is integrally mounted on, and is non-detachably attached to, said rubber body (i) which provides elasticity to said operable photovoltaic device and its layers, and (ii) which absorbs mechanical shocks and forces that are applied onto said operable photovoltaic device and its layers.

In some embodiments, the rubber body securely and directly holds in place said operable photovoltaic device, by being directly molded to a bottom-side of said operable photovoltaic device, and without any screw-based connection or glue-based connection or pin-based connection.

In some embodiments, the rubber body securely and directly holds in place said operable photovoltaic device, by being directly molded (i) beneath a bottom-side of said operable photovoltaic device, and also (ii) horizontally adjacently to two or more edges of said operable photovoltaic device, and without any screw-based connection or glue-based connection or pin-based connection.

In some embodiments, the apparatus is a pavement tile that can be stepped-upon by a human; wherein the pavement tile comprises said operable photovoltaic device at its upper region; wherein the operable photovoltaic device of the pavement tile is a flexible and rollable operable photovoltaic device; wherein the operable photovoltaic device of the pavement tile remains operable and non-damaged and non-cracked upon stepping by a human; wherein said rubber body, that is molded to said operable photovoltaic device and immediately beneath said operable photovoltaic device, absorbs mechanical shocks and mechanical forces that are applied onto said operable photovoltaic device by a stepping human.

In some embodiments, the apparatus is a traffic-related article (or a vehicular-traffic related article) selected from the group consisting of: a traffic sign, a traffic light, a traffic bollard; wherein the traffic-related article comprises said operable photovoltaic device at its upper region; wherein the operable photovoltaic device of the traffic-related article is a flexible and rollable operable photovoltaic device; wherein the operable photovoltaic device of the traffic-related article remains operable and non-damaged and non-cracked even upon application of downwardly-directed mechanical forces that are applied on said traffic-related article or on said operable photovoltaic device; wherein said rubber body, that is molded to said operable photovoltaic device and immediately beneath said operable photovoltaic device, absorbs mechanical shocks and mechanical forces, that are applied onto said operable photovoltaic device.

In some embodiments, the apparatus is a floating article selected from the group consisting of: a buoy, a floating marker; wherein the floating article comprises said operable photovoltaic device at its upper region; wherein the operable photovoltaic device of the floating article is a flexible and rollable operable photovoltaic device; wherein the operable photovoltaic device of the floating article remains operable and non-damaged and non-cracked even upon application of downwardly-directed mechanical forces that are applied on said floating article or on said operable photovoltaic device; wherein said rubber body, that is molded to said operable photovoltaic device and immediately beneath said operable photovoltaic device, absorbs mechanical shocks and mechanical forces that are applied onto said operable photovoltaic device.

In some embodiments, the apparatus is a vehicular component that is selected from the group consisting of: (i) a rubber-based vehicular component, (ii) a rubber-based protective element that is configured to cover or to protect a part of a vehicle; wherein the vehicular component comprises said operable photovoltaic device at its upper region; wherein the operable photovoltaic device of the vehicular component is a flexible and rollable operable photovoltaic device; wherein the operable photovoltaic device of the vehicular component remains operable and non-damaged and non-cracked even upon application of downwardly-directed mechanical forces that are applied on said vehicular component or on said operable photovoltaic device; wherein said rubber body, that is molded to said operable photovoltaic device and immediately beneath said operable photovoltaic device, absorbs mechanical shocks and mechanical forces that are applied onto said operable photovoltaic device.

In some embodiments, the apparatus is a tile selected from the group consisting of: a roof tile, a flooring tile, a pavement tile; wherein the tile comprises said operable photovoltaic device at its upper region; wherein said operable photovoltaic device occupies at least 99 percent of an entirety of an upper-side surface of said tile; wherein the operable photovoltaic device of said tile is a flexible and rollable operable photovoltaic device; wherein the operable photovoltaic device of said tile remains operable and non-damaged and non-cracked even upon application of downwardly-directed mechanical forces that are applied on said tile or on said operable photovoltaic device; wherein said rubber body, that is molded to said operable photovoltaic device and immediately beneath said operable photovoltaic device, absorbs mechanical shocks and mechanical forces that are applied onto said operable photovoltaic device.

In some embodiments, the apparatus is a tile selected from the group consisting of: a roof tile, a flooring tile, a pavement tile; wherein the tile comprises said operable photovoltaic device at its upper region; wherein said operable photovoltaic device occupies between 75 to 99 percent of an entirety of an upper-side surface of said tile; wherein a rubber frame occupies between 1 to 25 percent of the entirety of the upper-side surface of said tile; wherein said rubber frame is integrally connected to said operable photovoltaic device via a molded rubber connection; wherein the operable photovoltaic device of said tile is a flexible and rollable operable photovoltaic device; wherein the operable photovoltaic device of said tile remains operable and non-damaged and non-cracked even upon application of downwardly-directed mechanical forces that are applied on said tile or on said operable photovoltaic device; wherein said rubber body, that is molded to said operable photovoltaic device and immediately beneath said operable photovoltaic device, absorbs mechanical shocks and mechanical forces that are applied onto said operable photovoltaic device.

In some embodiments, the apparatus is formed, exclusively, of: (i) said operable photovoltaic device, and (ii) a rubber material that entirely consists or recycled scrap rubber.

In some embodiments, a device comprises: (a) a rubber body, formed of one or more solidified, compacted, previously-heated rubber materials, selected from the group consisting of: virgin unused rubber material, recycled rubber, scrap rubber, rubber pellets, rubber granules, rubber lumps, rubber strips; and (b) an operable photovoltaic device, that is configured to generate electricity from light via the photovoltaic effect. The operable photovoltaic device is entirely buried within said rubber body, and is integrally held within said rubber body via a molded connection and holding mechanism which molds together (i) said rubber body and (ii) said operable photovoltaic device; wherein said operable photovoltaic device has a sunny-side surface that is intended to face a light source and that is operable to convert incoming light to electricity; and also has a dark-side surface that is generally opposite to said sunny-side surface; wherein at least a portion of molded rubber, that is between the sunny-side surface of the operable photovoltaic device and a surrounding environment, is at least 50 percent transparent or translucent and enables passage of light there-through from said surrounding environment to said sunny-side surface of the operable photovoltaic device.

In some embodiments, said operable photovoltaic device, that is entirely buried within said rubber body, is curved and non-planar; wherein a top surface of said rubber body is also curved and non-planar; wherein the curved and non-planar structure of the operable photovoltaic device, and the curved and non-planar structure of the top surface of the rubber body, enable said molded article to protectively fit over another product which is curved and non-planar.

In some embodiments, said operable photovoltaic device is entirely buried beneath, and a sunny-side surface of the operable photovoltaic device is covered by, a top-side protective / encapsulation layer which includes at least one of: (I) a non-rigid top-side protection sheet, that is at least 75 percent transparent or translucent; (II) a non-rigid top-side encapsulant, that is at least 75 percent transparent or translucent; wherein said top-side protective / encapsulation layer comprises one or more of: (i) a non-rigid glass fiber weave, that is impregnated or interwoven with a resin, (ii) a layer of thermoset-based composite materials that includes at least one of epoxy, polyester, polyurethane.

In some embodiments, a manufacturing method comprises: (a) producing an operable photovoltaic device that is able to convert light into electricity, and that is flexible and rollable; and which comprises a semiconductor substrate having a plurality of non-transcending craters that penetrate into from 80 percent to 99.9 percent of a depth of said semiconductor substrate; wherein the plurality of non-transcending craters in said semiconductor substrate, segment said semiconductor substrate and said operable photovoltaic device into a plurality of sub-regions, and provide to said operable photovoltaic device properties of absorption and dissipation of mechanical forces and/or mechanical shocks and/or mechanical pressure and/or thermal forces, and provide to said operable photovoltaic device an ability to remain operable even after being subjected to high-temperature and high-pressure of a rubber article manufacturing machine; (b) placing within a mold cavity of a rubber molding machine, at an inner-side of said mold cavity, said operable photovoltaic device that is able to convert light into electricity and which is a flexible and rollable operable photovoltaic device; (c) placing one or more rubber materials, (c1) inside said mold cavity or (c2) near said mold cavity within said molding machine or (c3) at a container of rubber materials that is intended for heating and injection or transfer into the mold cavity; wherein the one or more rubber materials comprise one or more materials selected from the group consisting of: virgin unused rubber material, recycled rubber, scrap rubber, rubber pellets, rubber granules, rubber lumps, rubber strips; (d) applying heat and compression to the one or more rubber materials, to generate a molded rubber body that is integrally molded to at least a bottom-side of the operable photovoltaic device; (e) after a cooling-down period of time, extracting from the molding machine an integrated article that integrally comprises (I) said operable photovoltaic device, that is molded directly via a molded rubber connection to (II) said molded rubber body.

In some embodiments, the operable photovoltaic device is placed within a bottom-member of a mold of said molding machine, with its sunny-side or active side touching said mold and facing away from a cavity of said mold; wherein the one or more rubber materials are placed or poured into said cavity and on top of said operable photovoltaic device, and touch the dark side or the non-active side of the operable photovoltaic device, and do not touch the sunny-side or active side of the operable photovoltaic device; wherein the method comprises heating and compacting said one or more rubber materials that are located within said cavity and on top of said operable photovoltaic device within the mold.

In some embodiments, step (d) comprises: performing rubber injection molding, of said one or more rubber materials that are heated and injected into said mold cavity of said molding machine, which already has said operable photovoltaic device pre-inserted into said mold cavity; wherein the operable photovoltaic device, which is a flexible and rollable operable photovoltaic device, withstands heat and pressures of the rubber injection molding, and remains operable and non-damaged and non-cracked during and after the rubber injection molding.

In some embodiments, step (d) comprises: performing rubber compression molding of said one or more rubber materials, which are provided into said mold cavity as one or more pre-formed lumps of rubber, and which are then compacted and compressed into said mold cavity of said molding machine, which already has said operable photovoltaic device pre-inserted into said mold cavity; wherein the operable photovoltaic device, which is a flexible and rollable operable photovoltaic device, withstands heat and pressures of the rubber compression molding, and remains operable and non-damaged and non-cracked during and after the rubber compression molding.

In some embodiments, step (d) comprises: performing rubber transfer-and-compression molding of said one or more rubber materials, which are provided into said mold cavity as one or more pre-formed lumps of rubber, and which are then transferred via one or more sprues and are compacted and compressed into said mold cavity of said molding machine, which already has said operable photovoltaic device pre-inserted into said mold cavity; wherein the operable photovoltaic device, which is a flexible and rollable operable photovoltaic device, withstands heat and pressures of the rubber transfer-and-compression molding, and remains operable and non-damaged and non-cracked during and after the rubber transfer-and-compression molding.

In some embodiments, the manufacturing method creates a molded, rubber-based, connection between (i) said operable photovoltaic device and (ii) a rubber body that is created via molding of the one or more rubber materials; wherein said molded rubber-based connection is created concurrently with creation of said rubber body, at the same time and by the same single rubber molding operation.

In some embodiments, the operable photovoltaic device is temporarily held in place, within a mold cavity of the mold of the rubber molding machine, prior to rubber molding and/or during rubber molding, via at least one of: suction force, vacuum force, an anchoring mechanism, an adhesive, friction force, pressure force, magnetic force.

In some embodiments, the operable photovoltaic device is placed within the mold cavity of the rubber molding machine in a position wherein the sunny-side surface of the operable photovoltaic device is facing a bottom-side member of the mold, and wherein the sunny-side surface of the operable photovoltaic device is directly touching said bottom-side member of the mold.

In some embodiments, the manufacturing method comprises: injecting heated and compacted rubber material into the mold cavity of the rubber molding machine, wherein injected heated and compacted rubber material surrounds some, but not all, of the sides of the operable photovoltaic device; and avoiding coverage or obstruction by injected heated and compacted rubber material of the sunny-side surface of the operable photovoltaic device.

In some embodiments, the manufacturing method comprises: injecting heated and compacted rubber material into the mold cavity of the rubber molding machine, wherein injected heated and compacted rubber material surrounds all the sides of the operable photovoltaic device; wherein said injecting comprises creating a rubber-based article in which the operable photovoltaic device is entirely buried within said molded rubber body of said molded article; wherein a rubber region that is located above a sunny-side of the operable photovoltaic device is at least partially transparent or translucent and enables passage of light there-through to the sunny-side of the operable photovoltaic device.

In some embodiments, said operable photovoltaic device is operable to convert light to electricity prior to insertion of said photovoltaic device into the mold of the rubber molding machine; wherein said operable photovoltaic device remains operable to convert light to electricity after it is integrated, via rubber molding, into said molded article.

In some embodiments, said operable photovoltaic device is a curved, non-planar, flexible and rollable operable photovoltaic device; wherein said placing comprises: temporarily attaching said curved, non-planar, flexible and rollable operable photovoltaic device, to a non-planar inner-surface of the mold of the rubber molding machine.

In some embodiments, said operable photovoltaic device is a curved, non-planar, flexible and rollable operable photovoltaic device; wherein the method comprises: forming a molded rubber article that has a non-planar top surface, which securely holds via a rubber molding connection, said curved, non-planar, flexible and rollable operable photovoltaic device.

In some embodiments, the method comprises: molding a foaming agent or a foam-creating agent, together with molding of the one or more rubber materials; and forming a molded rubber article that has enhanced buoyancy on water.

In some embodiments, a manufacturing system comprises: (a) a photovoltaic device production unit, configured to produce an operable photovoltaic device that is able to convert light into electricity, and that is flexible and rollable; and which comprises a semiconductor substrate having a plurality of non-transcending craters that penetrate into from 80 percent to 99.9 percent of a depth of said semiconductor substrate; wherein the plurality of non-transcending craters in said semiconductor substrate, segment said semiconductor substrate and said operable photovoltaic device into a plurality of sub-regions, and provide to said operable photovoltaic device properties of absorption and dissipation of mechanical forces and/or mechanical shocks and/or mechanical pressure and/or thermal forces, and provide to said operable photovoltaic device an ability to remain operable even after being subjected to high-temperature and high-pressure of a rubber article manufacturing machine; (b) a photovoltaic device placement unit, configured to place within a mold cavity of a rubber molding machine, at an inner-side of said mold cavity, said operable photovoltaic device that is able to convert light into electricity and which is a flexible and rollable operable photovoltaic device; (c) a raw rubber placement unit, configured to place one or more rubber materials, (c1) inside said mold cavity or (c2) near said mold cavity within said molding machine or (c3) at a container of rubber materials that is intended for heating and injection or transfer into the mold cavity; wherein the one or more rubber materials comprise one or more materials selected from the group consisting of: virgin unused rubber material, recycled rubber, scrap rubber, rubber pellets, rubber granules, rubber lumps, rubber strips; (d) a heating and compression unit, configured to apply heat and compression to the one or more rubber materials, to generate a molded rubber body that is integrally molded to at least a bottom-side of the operable photovoltaic device; (e) an integrated article extraction unit, configured to wait a cooling-down period of time and then to extract from the rubber molding machine an integrated article that integrally comprises (I) said operable photovoltaic device, that is molded directly via a molded rubber connection to (II) said molded rubber body.

Functions, operations, components and/or features described herein with reference to one or more embodiments, may be combined with, or may be utilized in combination with, one or more other functions, operations, components and/or features described herein with reference to one or more other embodiments, or vice versa.

While certain features of some embodiments have been illustrated and described herein, many modifications, substitutions, changes, and equivalents may occur to those skilled in the art. Accordingly, the claims are intended to cover all such modifications, substitutions, changes, and equivalents.

What is claimed is:

1. An apparatus comprising:
(a) a rubber body, formed of one or more solidified, compacted, previously-heated rubber materials, selected from the group consisting of: virgin unused rubber material, recycled rubber, scrap rubber, rubber pellets, rubber granules, rubber lumps, rubber strips;
(b) an operable photovoltaic device, that is configured to generate electricity from light via the photovoltaic effect;
wherein the operable photovoltaic device is integrally held on top of said rubber body, via a molded connection and holding mechanism which molds together (i) said rubber body and (ii) said operable photovoltaic device.

2. The apparatus of claim 1,
wherein the operable photovoltaic device is held in place on said rubber body only via molding together of said operable photovoltaic device with said one or more rubber materials, and not via any screws or any glue or any detachable attachment mechanism.

3. The apparatus of claim 2,
wherein the operable photovoltaic device is a flexible and rollable operable photovoltaic device, and comprises a semiconductor substrate having a plurality of non-transcending craters that penetrate into from 80 percent to 99.9 percent of a depth of said semiconductor substrate;
wherein the plurality of non-transcending craters in said semiconductor substrate, segment said semiconductor substrate and said operable photovoltaic device into a plurality of sub-regions, and provide to said operable photovoltaic device properties of absorption and dissipation of mechanical forces and/or mechanical shocks and/or mechanical pressure and/or thermal forces, and provide to said operable photovoltaic device an ability to remain operable even after being subjected to high-temperature and high-pressure of a rubber article manufacturing machine.

4. The apparatus of claim 2, wherein the operable photovoltaic device is a flexible and rollable operable photovoltaic device which comprises the following layers:
(I) a non-rigid top-side protection sheet, that is at least 75 percent transparent or translucent;
(II) a non-rigid top-side encapsulant, that is at least 75 percent transparent or translucent;
(III) an array of solar cells, that are inter-connected in series and/or in parallel;
(IV) a non-rigid bottom-side encapsulant;
(V) a non-rigid bottom-side protection sheet;
wherein said operable photovoltaic device is integrally mounted on, and is non-detachably attached to, said rubber body (i) which provides elasticity to said operable photovoltaic device and its layers, and (ii) which absorbs mechanical shocks and forces that are applied onto said operable photovoltaic device and its layers.

5. The apparatus of claim 2, wherein the operable photovoltaic device is a flexible and rollable operable photovoltaic device which comprises the following layers:
(I) a non-rigid top-side protection sheet, that is at least 75 percent transparent or translucent;
(II) a non-rigid top-side encapsulant, that is at least 75 percent transparent or translucent;
wherein at least one of: the non-rigid top-side protection sheet, and the non-rigid top-side encapsulant, comprises one or more of: (i) a non-rigid glass fiber weave, that is impregnated or interwoven with a resin, (ii) a layer of thermoset-based composite materials that includes at least one of epoxy, polyester, polyurethane;
(III) an array of solar cells, that are inter-connected in series and/or in parallel;
(IV) a non-rigid bottom-side encapsulant;
(V) a non-rigid bottom-side protection sheet;
wherein at least one of: the non-rigid bottom-side protection sheet, and the non-rigid bottom-side encapsulant, comprises one or more of: (i) a non-rigid glass fiber weave, that is impregnated or interwoven with a resin, (ii) a layer of thermoset-based composite materials that includes at least one of epoxy, polyester, polyurethane;
wherein said operable photovoltaic device is integrally mounted on, and is non-detachably attached to, said rubber body (i) which provides elasticity to said operable photovoltaic device and its layers, and (ii) which absorbs mechanical shocks and forces that are applied onto said operable photovoltaic device and its layers.

6. The apparatus of claim 1,
wherein the rubber body securely and directly holds in place said operable photovoltaic device, by being directly molded to a bottom-side of said operable photovoltaic device, and without any screw-based connection or glue-based connection or pin-based connection.

7. The apparatus of claim 1,
wherein the rubber body securely and directly holds in place said operable photovoltaic device, by being directly molded (i) beneath a bottom-side of said operable photovoltaic device, and also (ii) horizontally adjacently to two or more edges of said operable photovoltaic device, and without any screw-based connection or glue-based connection or pin-based connection.

8. The apparatus of claim 2,
wherein the apparatus is a pavement tile that can be stepped-upon by a human;
wherein the pavement tile comprises said operable photovoltaic device at its upper region;
wherein the operable photovoltaic device of the pavement tile is a flexible and rollable operable photovoltaic device;
wherein the operable photovoltaic device of the pavement tile remains operable and non-damaged and non-cracked upon stepping by a human;
wherein said rubber body, that is molded to said operable photovoltaic device and immediately beneath said operable photovoltaic device, absorbs mechanical shocks and mechanical forces that are applied onto said operable photovoltaic device by a stepping human.

9. The apparatus of claim 2,
wherein the apparatus is a traffic-related article selected from the group consisting of: a traffic sign, a traffic light, a traffic bollard;
wherein the traffic-related article comprises said operable photovoltaic device at its upper region;
wherein the operable photovoltaic device of the traffic-related article is a flexible and rollable operable photovoltaic device;
wherein the operable photovoltaic device of the traffic-related article remains operable and non-damaged and non-cracked even upon application of downwardly-directed mechanical forces that are applied on said traffic-related article or on said operable photovoltaic device;
wherein said rubber body, that is molded to said operable photovoltaic device and immediately beneath said operable photovoltaic device, absorbs mechanical shocks and mechanical forces, that are applied onto said operable photovoltaic device.

10. The apparatus of claim 2,
wherein the apparatus is a floating article selected from the group consisting of: a buoy, a floating marker;
wherein the floating article comprises said operable photovoltaic device at its upper region;
wherein the operable photovoltaic device of the floating article is a flexible and rollable operable photovoltaic device;
wherein the operable photovoltaic device of the floating article remains operable and non-damaged and non-cracked even upon application of downwardly-directed mechanical forces that are applied on said floating article or on said operable photovoltaic device;
wherein said rubber body, that is molded to said operable photovoltaic device and immediately beneath said operable photovoltaic device, absorbs mechanical shocks and mechanical forces that are applied onto said operable photovoltaic device.

11. The apparatus of claim 2,
wherein the apparatus is a vehicular component that is selected from the group consisting of: (i) a rubber-based vehicular component, (ii) a rubber-based protective element that is configured to cover or to protect a part of a vehicle;
wherein the vehicular component comprises said operable photovoltaic device at its upper region;
wherein the operable photovoltaic device of the vehicular component is a flexible and rollable operable photovoltaic device;
wherein the operable photovoltaic device of the vehicular component remains operable and non-damaged and non-cracked even upon application of downwardly-directed mechanical forces that are applied on said vehicular component or on said operable photovoltaic device;
wherein said rubber body, that is molded to said operable photovoltaic device and immediately beneath said operable photovoltaic device, absorbs mechanical shocks and mechanical forces that are applied onto said operable photovoltaic device.

12. The apparatus of claim 2,
wherein the apparatus is a tile selected from the group consisting of: a roof tile, a flooring tile, a pavement tile;
wherein the tile comprises said operable photovoltaic device at its upper region;
wherein said operable photovoltaic device occupies at least 99 percent of an entirety of an upper-side surface of said tile;
wherein the operable photovoltaic device of said tile is a flexible and rollable operable photovoltaic device;
wherein the operable photovoltaic device of said tile remains operable and non-damaged and non-cracked even upon application of downwardly-directed mechanical forces that are applied on said tile or on said operable photovoltaic device;
wherein said rubber body, that is molded to said operable photovoltaic device and immediately beneath said operable photovoltaic device, absorbs mechanical shocks and mechanical forces that are applied onto said operable photovoltaic device.

13. The apparatus of claim 2,
wherein the apparatus is a tile selected from the group consisting of: a roof tile, a flooring tile, a pavement tile;
wherein the tile comprises said operable photovoltaic device at its upper region;
wherein said operable photovoltaic device occupies between 75 to 99 percent of an entirety of an upper-side surface of said tile;
wherein a rubber frame occupies between 1 to 25 percent of the entirety of the upper-side surface of said tile;
wherein said rubber frame is integrally connected to said operable photovoltaic device via a molded rubber connection;
wherein the operable photovoltaic device of said tile is a flexible and rollable operable photovoltaic device;
wherein the operable photovoltaic device of said tile remains operable and non-damaged and non-cracked even upon application of downwardly-directed mechanical forces that are applied on said tile or on said operable photovoltaic device;
wherein said rubber body, that is molded to said operable photovoltaic device and immediately beneath said operable photovoltaic device, absorbs mechanical shocks and mechanical forces that are applied onto said operable photovoltaic device.

14. The apparatus of claim 2,
wherein the apparatus is formed, exclusively, of: (i) said operable photovoltaic device, and (ii) a rubber material that entirely consists or recycled scrap rubber.

15. A device comprising:
(a) a rubber body, formed of one or more solidified, compacted, previously-heated rubber materials, selected from the group consisting of: virgin unused rubber material, recycled rubber, scrap rubber, rubber pellets, rubber granules, rubber lumps, rubber strips;
(b) an operable photovoltaic device, that is configured to generate electricity from light via the photovoltaic effect;
wherein the operable photovoltaic device is entirely buried within said rubber body, and is integrally held within said rubber body via a molded connection and holding mechanism which molds together (i) said rubber body and (ii) said operable photovoltaic device;
wherein said operable photovoltaic device has a sunny-side surface that is intended to face a light source and that is operable to convert incoming light to electricity; and also has a dark-side surface that is generally opposite to said sunny-side surface;
wherein at least a portion of molded rubber, that is between the sunny-side surface of the operable photovoltaic device and a surrounding environment, is at least 50 percent transparent or translucent and enables passage of light there-through from said surrounding environment to said sunny-side surface of the operable photovoltaic device.

16. The device of claim 15,
wherein said operable photovoltaic device, that is entirely buried within said rubber body, is curved and non-planar;
wherein a top surface of said rubber body is also curved and non-planar;
wherein the curved and non-planar structure of the operable photovoltaic device, and the curved and non-planar structure of the top surface of the rubber body, enable said molded article to protectively fit over another product which is curved and non-planar.

17. The device of claim 15,
wherein said operable photovoltaic device is entirely buried beneath, and a sunny-side surface of the operable photovoltaic device is covered by, a top-side protective / encapsulation layer which includes at least one of:
(I) a non-rigid top-side protection sheet, that is at least 75 percent transparent or translucent;
(II) a non-rigid top-side encapsulant, that is at least 75 percent transparent or translucent;
wherein said top-side protective / encapsulation layer comprises one or more of: (i) a non-rigid glass fiber weave, that is impregnated or interwoven with a resin, (ii) a layer of thermoset-based composite materials that includes at least one of epoxy, polyester, polyurethane.

18. A manufacturing method, comprising:
(a) producing an operable photovoltaic device that is able to convert light into electricity, and that is flexible and rollable; and which comprises a semiconductor substrate having a plurality of non-transcending craters that penetrate into from 80 percent to 99.9 percent of a depth of said semiconductor substrate;
wherein the plurality of non-transcending craters in said semiconductor substrate, segment said semiconductor substrate and said operable photovoltaic device into a plurality of sub-regions, and provide to said operable photovoltaic device properties of absorption and dissipation of mechanical forces and/or mechanical shocks and/or mechanical pressure and/or thermal forces, and provide to said operable photovoltaic device an ability to remain operable even after being subjected to high-temperature and high-pressure of a rubber article manufacturing machine;
(b) placing within a mold cavity of a rubber molding machine, at an inner-side of said mold cavity, said operable photovoltaic device that is able to convert light into electricity and which is a flexible and rollable operable photovoltaic device;
(c) placing one or more rubber materials, (c1) inside said mold cavity or (c2) near said mold cavity within said molding machine or (c3) at a container of rubber materials that is intended for heating and injection or transfer into the mold cavity;
wherein the one or more rubber materials comprise one or more materials selected from the group consisting of: virgin unused rubber material, recycled rubber, scrap rubber, rubber pellets, rubber granules, rubber lumps, rubber strips;
(d) applying heat and compression to the one or more rubber materials, to generate a molded rubber body that is integrally molded to at least a bottom-side of the operable photovoltaic device;
(e) after a cooling-down period of time, extracting from the molding machine an integrated article that integrally comprises (I) said operable photovoltaic device, that is molded directly via a molded rubber connection to (II) said molded rubber body.

19. The manufacturing method of claim 18,
wherein the operable photovoltaic device is placed within a bottom-member of a mold of said molding machine, with its sunny-side or active side touching said mold and facing away from a cavity of said mold;
wherein the one or more rubber materials are placed or poured into said cavity and on top of said operable photovoltaic device, and touch the dark side or the non-active side of the operable photovoltaic device, and do not touch the sunny-side or active side of the operable photovoltaic device;
wherein the method comprises heating and compacting said one or more rubber materials that are located within said cavity and on top of said operable photovoltaic device within the mold.

20. The manufacturing method of claim 18,
wherein step (d) comprises:
performing rubber injection molding, of said one or more rubber materials that are heated and injected into said mold cavity of said molding machine, which already has said operable photovoltaic device pre-inserted into said mold cavity;
wherein the operable photovoltaic device, which is a flexible and rollable operable photovoltaic device, withstands heat and pressures of the rubber injection molding, and remains operable and non-damaged and non-cracked during and after the rubber injection molding.

21. The manufacturing method of claim 18,
wherein step (d) comprises:
performing rubber compression molding of said one or more rubber materials, which are provided into said mold cavity as one or more pre-formed lumps of rubber, and which are then compacted and compressed into said mold cavity of said molding machine, which already has said operable photovoltaic device pre-inserted into said mold cavity;
wherein the operable photovoltaic device, which is a flexible and rollable operable photovoltaic device, withstands heat and pressures of the rubber compression molding, and remains operable and non-damaged and non-cracked during and after the rubber compression molding.

22. The manufacturing method of claim 18,
wherein step (d) comprises:
performing rubber transfer-and-compression molding of said one or more rubber materials, which are provided into said mold cavity as one or more pre-formed lumps of rubber, and which are then transferred via one or more sprues and are compacted and compressed into said mold cavity of said molding machine, which already has said operable photovoltaic device pre-inserted into said mold cavity;
wherein the operable photovoltaic device, which is a flexible and rollable operable photovoltaic device, withstands heat and pressures of the rubber transfer-and-compression molding, and remains operable and non-damaged and non-cracked during and after the rubber transfer-and-compression molding.

23. The manufacturing method of claim 18,
wherein the manufacturing method creates a molded, rubber-based, connection between (i) said operable photovoltaic device and (ii) a rubber body that is created via molding of the one or more rubber materials;
wherein said molded rubber-based connection is created concurrently with creation of said rubber body, at the same time and by the same single rubber molding operation.

24. The manufacturing method of claim 18,
wherein the operable photovoltaic device is temporarily held in place, within a mold cavity of the mold of the rubber molding machine, prior to rubber molding and/or during rubber molding, via at least one of: suction force, vacuum force, an anchoring mechanism, an adhesive, friction force, pressure force, magnetic force.

25. The manufacturing method of claim 18,
wherein the operable photovoltaic device is placed within the mold cavity of the rubber molding machine in a position wherein the sunny-side surface of the operable photovoltaic device is facing a bottom-side member of the mold, and wherein the sunny-side surface of the operable photovoltaic device is directly touching said bottom-side member of the mold.

26. The manufacturing method of claim 18, comprising:
injecting heated and compacted rubber material into the mold cavity of the rubber molding machine, wherein injected heated and compacted rubber material surrounds some, but not all, of the sides of the operable photovoltaic device; and avoiding coverage or obstruction by injected heated and compacted rubber material of the sunny-side surface of the operable photovoltaic device.

27. The manufacturing method of claim 18, comprising:
injecting heated and compacted rubber material into the mold cavity of the rubber molding machine, wherein injected heated and compacted rubber material surrounds all the sides of the operable photovoltaic device; wherein said injecting comprises creating a rubber-based article in which the operable photovoltaic device is entirely buried within said molded rubber body of said molded article; wherein a rubber region that is located above a sunny-side of the operable photovoltaic device is at least partially transparent or translucent and enables passage of light there-through to the sunny-side of the operable photovoltaic device.

28. The manufacturing method of claim 18,
wherein said operable photovoltaic device is operable to convert light to electricity prior to insertion of said photovoltaic device into the mold of the rubber molding machine;
wherein said operable photovoltaic device remains operable to convert light to electricity after it is integrated, via rubber molding, into said molded article.

29. The manufacturing method of claim 18,
wherein said operable photovoltaic device is a curved, non-planar, flexible and rollable operable photovoltaic device;
wherein said placing comprises:
temporarily attaching said curved, non-planar, flexible and rollable operable photovoltaic device, to a non-planar inner-surface of the mold of the rubber molding machine.

30. The manufacturing method of claim 18,
wherein said operable photovoltaic device is a curved, non-planar, flexible and rollable operable photovoltaic device;
wherein the method comprises:
forming a molded rubber article that has a non-planar top surface, which securely holds via a rubber molding connection, said curved, non-planar, flexible and rollable operable photovoltaic device.

31. The manufacturing method of claim 18,
wherein the method comprises:
molding a foaming agent or a foam-creating agent, together with molding of the one or more rubber materials; and forming a molded rubber article that has enhanced buoyancy on water.

32. A manufacturing system, comprising:
(a) a photovoltaic device production unit,
configured to produce an operable photovoltaic device that is able to convert light into electricity, and that is flexible and rollable; and which comprises a semiconductor substrate having a plurality of non-transcending craters that penetrate into from 80 percent to 99.9 percent of a depth of said semiconductor substrate;
wherein the plurality of non-transcending craters in said semiconductor substrate, segment said semiconductor substrate and said operable photovoltaic device into a plurality of sub-regions, and provide to said operable photovoltaic device properties of absorption and dissipation of mechanical forces and/or mechanical shocks and/or mechanical pressure and/or thermal forces, and provide to said operable photovoltaic device an ability to remain operable even after being subjected to high-temperature and high-pressure of a rubber article manufacturing machine;
(b) a photovoltaic device placement unit,
configured to place within a mold cavity of a rubber molding machine, at an inner-side of said mold cavity, said operable photovoltaic device that is able to convert light into electricity and which is a flexible and rollable operable photovoltaic device;
(c) a raw rubber placement unit,
configured to place one or more rubber materials, (c1) inside said mold cavity or (c2) near said mold cavity within said molding machine or (c3) at a container of rubber materials that is intended for heating and injection or transfer into the mold cavity;
wherein the one or more rubber materials comprise one or more materials selected from the group consisting of: virgin unused rubber material, recycled rubber, scrap rubber, rubber pellets, rubber granules, rubber lumps, rubber strips;
(d) a heating and compression unit,
configured to apply heat and compression to the one or more rubber materials, to generate a molded rubber body that is integrally molded to at least a bottom-side of the operable photovoltaic device;
(e) an integrated article extraction unit,
configured to wait a cooling-down period of time and then to extract from the rubber molding machine an integrated article that integrally comprises (I) said operable photovoltaic device, that is molded directly via a molded rubber connection to (II) said molded rubber body.
